(19) United States
(12) Patent Application Publication
(10) Pub. No.: US 2023/0056323 A1
(43) Pub. Date: Feb. 23, 2023

(54) PLASMA PROCESSING APPARATUS AND ETCHING METHOD

(71) Applicant: Tokyo Electron Limited, Tokyo (JP)

(72) Inventors: Natsumi TORII, Miyagi (JP); Koichi NAGAMI, Miyagi (JP)

(73) Assignee: Tokyo Electron Limited, Tokyo (JP)

(21) Appl. No.: 17/889,632

(22) Filed: Aug. 17, 2022

(30) Foreign Application Priority Data
Aug. 17, 2021 (JP) 2021-132675
Jul. 22, 2022 (JP) 2022-116904

(51) Int. Cl. H01J 37/32; H01L 21/683; H01L 21/687

(52) U.S. Cl. CPC H01J 37/32642; H01L 21/6831; H01J 37/32174; H01L 21/68721; H01L 21/68742; H01J 2237/334

(57) ABSTRACT

A plasma processing apparatus comprising: a plasma processing chamber; a substrate support disposed in the plasma processing chamber, and including a lower electrode, an electrostatic chuck, and an edge ring disposed to surround a substrate mounted on the electrostatic chuck; a driving device; an upper electrode disposed above the substrate support. In an example, the apparatus further comprises a source RF power supply; a bias RF power supply configured to supply bias RF power to the lower electrode; at least one conductor; a DC power supply; an RF filter electrically; and a controller configured to control the driving device and the at least one variable passive element, and adjust an incident angle of an ion in the plasma with respect to an edge area of the substrate mounted on the electrostatic chuck.

### CROSS-REFERENCE TO RELATED APPLICATIONS

This application claims priority to Japanese Patent Application Nos. 2021-132675 filed on Aug. 17, 2021 and 2022-116904 filed on Jul. 22, 2022, respectively, the entire contents of which are incorporated herein by reference.

### TECHNICAL FIELD

The present disclosure relates to a plasma processing apparatus and an etching method.

### BACKGROUND

Japanese Laid-open Patent Publication No. 2017-228526 discloses a system for controlling directionality of an ion beam in an edge area in a plasma chamber. The system includes an RF generator configured to generate an RF signal, an impedance matching circuit for receiving the RF signal and generating a modified RF signal, and a plasma chamber. The plasma chamber includes an edge ring and a coupling ring receiving the modified RF signal. The coupling ring includes an electrode receiving the modified RF signal, and an electrode generating a capacitance between the edge rings and controlling the directionality of the ion beam.

### SUMMARY

A technique according to the present disclosure is to appropriately control an incident angle of an ion in plasma with respect to an edge area of a substrate in plasma processing.

In accordance with an aspect of the present disclosure, there is provided a plasma processing apparatus comprising: a plasma processing chamber; a substrate support disposed in the plasma processing chamber, and including a lower electrode, an electrostatic chuck, and an edge ring disposed to surround a substrate mounted on the electrostatic chuck; a driving device configured to move the edge ring in a vertical direction; an upper electrode disposed above the substrate support; a source RF power supply configured to supply source RF power to the upper electrode or the lower electrode to generate plasma from gas in the plasma processing chamber; a bias RF power supply configured to supply bias RF power to the lower electrode; at least one conductor contacting with the edge ring; a DC power supply configured to apply negative-polarity DC voltage to the edge ring via the at least one conductor; an RF filter electrically connected between the at least one conductor and the DC power supply, and including at least one variable passive element; and a controller configured to control the driving device and the at least one variable passive element, and adjust an incident angle of an ion in the plasma with respect to an edge area of the substrate mounted on the electrostatic chuck.

### BRIEF DESCRIPTION OF THE DRAWINGS

FIG. 1 is a longitudinal cross-sectional view schematically illustrating a configuration of an etching device according to the present embodiment.

FIG. 2A is a longitudinal cross-sectional view schematically illustrating a configuration on the periphery of an edge ring according to the present embodiment.

FIG. 2B is a longitudinal cross-sectional view schematically illustrating a configuration on the periphery of an edge ring according to the present embodiment.

FIG. 3A is an explanatory diagram illustrating a change in shape of a sheath and generation of an inclination of an incident direction of an ion due to exhaustion of the edge ring.

FIG. 3B is an explanatory diagram illustrating a change in shape of a sheath and generation of an inclination of an incident direction of an ion due to exhaustion of the edge ring.

FIG. 4A is an explanatory diagram illustrating a change in shape of a sheath and generation of an inclination of an incident direction of an ion.

FIG. 4B is an explanatory diagram illustrating a change in shape of a sheath and generation of an inclination of an incident direction of an ion.

FIG. 5 is an explanatory diagram illustrating an example of a control method of a tilt angle.

FIG. 6 is an explanatory diagram illustrating an example of a control method of a tilt angle.

FIG. 7 is an explanatory diagram illustrating an example of a control method of a tilt angle.

FIG. 8 is an explanatory diagram illustrating an example of a control method of a tilt angle.

FIG. 9 is a longitudinal cross-sectional view schematically illustrating a configuration on the periphery of an edge ring according to another embodiment.

FIG. 10A is a longitudinal cross-sectional view illustrating an example of a configuration of a connector.

FIG. 10B is a longitudinal cross-sectional view illustrating an example of a configuration of a connector.

FIG. 10C is a longitudinal cross-sectional view illustrating an example of a configuration of a connector.

FIG. 10D is a longitudinal cross-sectional view illustrating an example of a configuration of a connector.

FIG. 10E is a longitudinal cross-sectional view illustrating an example of a configuration of a connector.

FIG. 10F is a longitudinal cross-sectional view illustrating an example of a configuration of a connector.

FIG. 11A is a longitudinal cross-sectional view illustrating an example of a configuration of a connector.

FIG. 11B is a longitudinal cross-sectional view illustrating an example of a configuration of a connector.

FIG. 11C is a longitudinal cross-sectional view illustrating an example of a configuration of a connector.

FIG. 11D is a longitudinal cross-sectional view illustrating an example of a configuration of a connector.

FIG. 11E is a longitudinal cross-sectional view illustrating an example of a configuration of a connector.

FIG. 11F is a longitudinal cross-sectional view illustrating an example of a configuration of a connector.

FIG. 11G is a longitudinal cross-sectional view illustrating an example of a configuration of a connector.

FIG. 12A is a plan view illustrating an example of a configuration of a connector.

FIG. 12B is a plan view illustrating an example of a configuration of a connector.

FIG. 12C is a plan view illustrating an example of a configuration of a connector.

FIG. 13A is an explanatory diagram schematically illustrating an example of a configuration of the connector and a variable passive element.

FIG. 13B is an explanatory diagram schematically illustrating an example of a configuration of the connector and a variable passive element.

FIG. 13C is an explanatory diagram schematically illustrating an example of a configuration of the connector and a variable passive element.

FIG. 14A is a longitudinal cross-sectional view illustrating an example of a configuration of the connector and a driving device.

FIG. 14B is a longitudinal cross-sectional view illustrating an example of a configuration of the connector and a driving device.

FIG. 14C is a longitudinal cross-sectional view illustrating an example of a configuration of the connector and a driving device.

FIG. 14D is a longitudinal cross-sectional view illustrating an example of a configuration of the connector and a driving device.

FIG. 15A is a longitudinal cross-sectional view illustrating an example of a configuration of the connector and the driving device.

FIG. 15B is a longitudinal cross-sectional view illustrating an example of a configuration of the connector and the driving device.

FIG. 15C is a longitudinal cross-sectional view illustrating an example of a configuration of the connector and the driving device.

FIG. 15D is a longitudinal cross-sectional view illustrating an example of a configuration of the connector and the driving device.

FIG. 16 is a longitudinal cross-sectional view schematically illustrating a configuration on the periphery of an edge ring according to another embodiment.

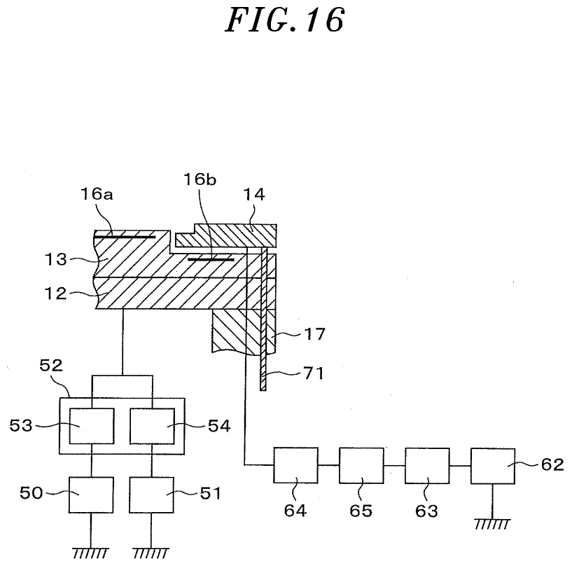

FIG. 17 is an explanatory diagram illustrating an example of a control method of a tilt angle.

FIG. 18 is an explanatory diagram illustrating an example of a control method of a tilt angle.

### DETAILED DESCRIPTION

In a manufacturing process of a semiconductor device, plasma processing such as etching is performed in a semiconductor wafer (hereinafter, referred to as “wafer”). In the plasma processing, plasma is generated by exciting processing gas, and the wafer is processed by the plasma.

The plasma processing is performed by a plasma processing apparatus. The plasma processing apparatus generally has a chamber, stage, and a radio frequency (RF) power supply. In one example, the radio frequency power supply includes a first radio frequency power supply and a second radio frequency power supply. The first radio frequency power supply supplies first radio frequency power to generate plasma of gas in the chamber. The second radio frequency power supply supplies second radio frequency power for bias to a lower electrode to draw ions into the wafer. The stage is provided in the chamber. The stage has the lower electrode and an electrostatic chuck. In one example, an edge ring is placed on the electrostatic chuck so as to surround the wafer mounted on the electrostatic chuck. The edge ring is provided to enhance the uniformity of the plasma processing for the wafer.

The edge ring is exhausted and the thickness of the edge ring is reduced as the time for which the plasma processing is performed elapses. When the thickness of the edge ring decreases, a shape of a sheath above the edge ring and an edge area of the wafer is changed. When the shape of the sheath is changed as such, an incident direction of the ion for the edge area of the wafer is inclined to a vertical direction. As a result, a concave portion formed in the edge area of the wafer is inclined toward a thickness direction of the wafer.

In order to form the concave portion that extends in the thickness direction of the wafer in the edge area of the wafer, it is necessary to adjust an inclination of the incident direction of the ion on the edge area of the wafer. Therefore, in order to control the incident direction (directionality of an ion beam) of the ion on the edge area, for example, it is proposed that a capacitance is generated between an electrode of a coupling ring and the edge ring as described above in Japanese Laid-open Patent Publication No. 2017-228526.

However, even if the incident angle is intended to be controlled simply by generating the capacitance, a control range may be limited. Further, it is desirable to suppress an exchange frequency of the edge ring according to exhaustion, but the incident angle of the ion may not be sufficiently controlled simply by generating the capacitance, and in this case, the exchange frequency of the edge ring may not be lowered.

In the technique according to the present disclosure, a tilt angle is appropriately controlled, such that the ion vertically enters into the edge area of a substrate during the etching.

Hereinafter, an etching device as the plasma processing apparatus according to the present embodiment, and an etching method will be described with reference to drawings. Further, in the present specification and drawings, the same reference numerals are given to elements having substantially the same functional configuration, so a redundant description will be omitted.

<Etching Device>

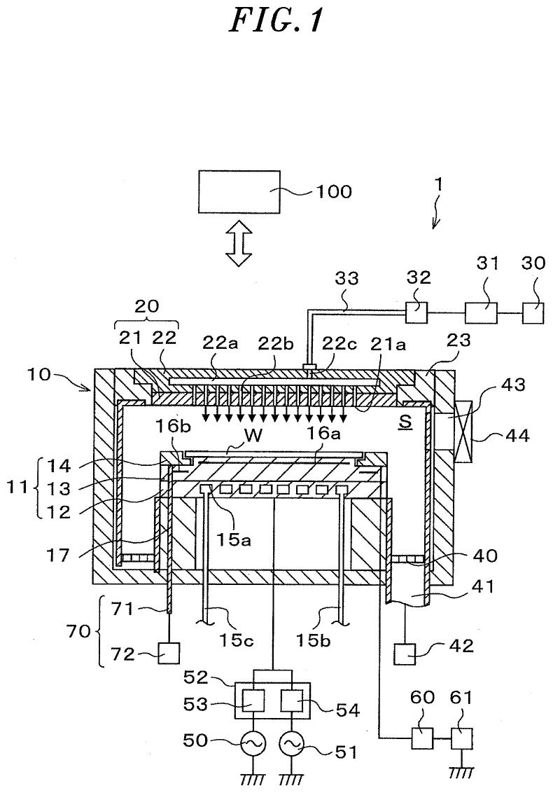

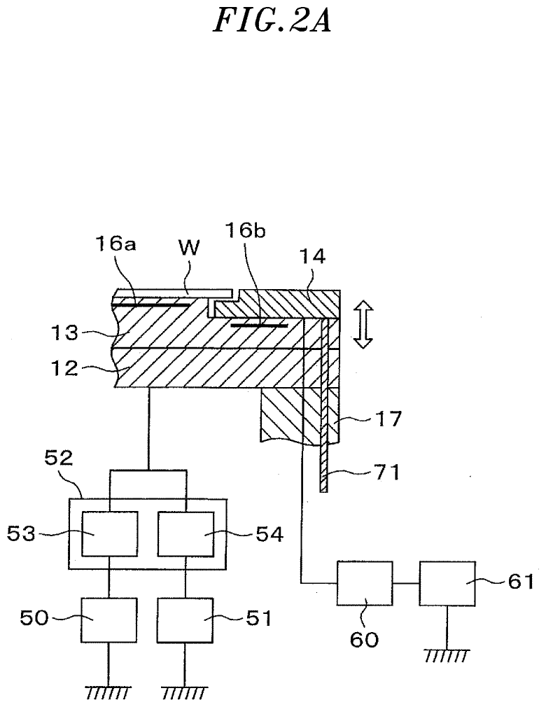

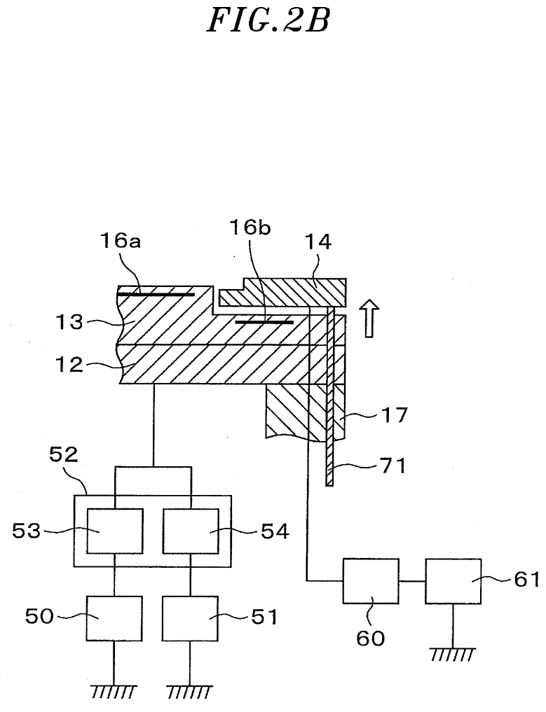

First, the etching device according to the present embodiment will be described. FIG. 1 is a longitudinal cross-sectional view schematically illustrating a configuration of an etching device 1. FIGS. 2A and 2B are longitudinal cross-sectional views schematically illustrating a configuration on the periphery of an edge ring according to the present embodiment. The etching device 1 is a capacitively coupled etching device. In the etching device 1, etching is performed for a wafer W as the substrate.

As illustrated in FIG. 1, the etching device 1 has a substantially cylindrical plasma processing chamber, e.g., a chamber 10. In the chamber 10, a processing space S where plasma is generated is partitioned inside the chamber 10. The chamber 10 is made of aluminum, for example. The chamber 10 is connected to a ground potential.

Inside the chamber 10, a stage 11 as a substrate support on which the wafer W is mounted is accommodated. The stage 11 has a lower electrode 12, an electrostatic chuck 13, and an edge ring 14. Further, an electrode plate (not illustrated) made of aluminum may be provided on a lower surface of the lower electrode 12, for example.

The lower electrode 12 is made of a conductive material, e.g., metal such as aluminum, and has a substantially disk shape.

Further, the stage 11 may include a temperature control module configured to control at least one of the electrostatic chuck 13, the edge ring 14, and the wafer W at a desired temperature. The temperature control module may include a heater, a flow path, or a combination thereof. A temperature control medium such as refrigerant or heat transfer gas flows on the flow path.

In one example, a flow path 15a is formed inside the lower electrode 12. The temperature control medium is supplied to the flow path 15a from a chiller unit (not illustrated) provided outside the chamber 10 via an inlet pipe 15b. The temperature control medium supplied to the flow path 15a returns to the chiller unit via an outlet path 15c. By circulating the temperature control medium inside the flow path 15a, e.g., refrigerant such as cooling water, the electrostatic chuck 13, the edge ring 14, and the wafer W may be cooled at a desired temperature.

The electrostatic chuck 13 is provided on the lower electrode 12. In one example, the electrostatic chuck 13 is a member configured to adsorb and hold both the wafer W and the edge ring 14 by electrostatic force. An upper surface of a center of the electrostatic chuck 13 is formed to be higher than an upper surface of a peripheral portion. The upper surface of the center of the electrostatic chuck 13 becomes a wafer mounted surface on which the wafer W is mounted, and in one example, the upper surface of the peripheral portion of the electrostatic chuck 13 becomes an edge ring mounted surface on which the edge ring 14 is mounted.

In one example, a first electrode 16a for adsorbing and holding the wafer W is provided at the center inside the electrostatic chuck 13. A second electrode 16b for adsorbing and holding the edge ring 14 is provided on the peripheral portion inside the electrostatic chuck 13. The electrostatic chuck 13 has a configuration in which the electrodes 16a and 16b are interposed between insulations made of an insulating material.

Direct current (DC) voltage from a DC power supply (not illustrated) is applied to the first electrode 16a. By the electrostatic force generated by the applied DC voltage, the wafer W is adsorbed and held on the upper surface of the center of the electrostatic chuck 13. Similarly, the DC voltage from the DC power supply (not illustrated) is applied to the second electrode 16b. In one example, by the electrostatic force generated by the applied DC voltage, the edge ring 14 is adsorbed and held on the upper surface of the peripheral portion of the electrostatic chuck 13.

Further, in the present embodiment, the center of the electrostatic chuck 13 provided in the first electrode 16a and the peripheral portion provided in the second electrode 16b are integrated, but the center and the peripheral portion may be separated. Further, both the first electrode 16a and the second electrode 16b may be unipolar or bipolar.

Further, in the present embodiment, the edge ring 14 is electrostatically adsorbed on the electrostatic chuck 13 by applying the DC voltage to the second electrode 16b, but a holding method of the edge ring 14 is not limited thereto. For example, the edge ring 14 may be adsorbed and held by using an adsorption sheet and held by clamping the edge ring 14. Alternatively, the edge ring 14 may be held by a weight of the edge ring 14 itself.

The edge ring 14 is a ring-shaped member to surround the wafer W mounted on the upper surface of the center of the electrostatic chuck 13. The edge ring 14 is provided to enhance the uniformity of the etching. For this reason, the edge ring 14 is made of a material selected appropriately according to the etching, and may have conductivity and may be made of Si or SiC, for example.

The stage 11 configured as such is fastened to a substantially cylindrical support member 17 provided on the bottom of the chamber 10. The support member 17 is constituted by an insulator such as ceramics and quartz.

A shower head 20 is provided above the stage 11 to face the stage 11. The shower head 20 has an electrode plate 21 disposed in contact with the processing space S, and an electrode support 22 provided above the electrode plate 21. The electrode plate 21 serves as an upper electrode which forms a pair with the lower electrode 12. When the first radio frequency power supply 50 is electrically connected to the lower electrode 12 as described below, the shower head 20 is connected to the ground potential. Further, the shower head 20 is supported on an upper portion (ceiling surface) of the chamber 10 via an insulative shielding member 23.

A plurality of gas injection holes 21a for supplying processing gas sent from a gas diffusion chamber 22a to be described below to the processing space S is formed in the electrode plate 21. The electrode plate 21 is constituted by a conductor or a semiconductor having a low electric resistance rate with little Joule's heat which is generated, for example.

The electrode support 22 detachably supports the electrode plate 21. The electrode support 22 has a configuration in which a membrane having plasma resistance is formed on the surface of the conductive material such as aluminum. The membrane may be a membrane formed by anode oxidation treatment or a membrane made of ceramics such as yttrium oxide. The gas diffusion chamber 22a is formed inside the electrode support 22. A plurality of gas distribution holes 22b which communicates with the gas injection holes 21a is formed from the gas diffusion chamber 22a. Further, a gas introduction hole 22c connected to a gas supply pipe 33 to be described below is formed in the gas diffusion chamber 22a.

Further, a gas supply source group 30 supplying the processing gas to the gas diffusion chamber 22a is connected to the electrode support 22 via a flow control device group 31, a valve group 32, the gas supply pipe 33, and the gas introduction hole 22c.

The gas supply source group 30 has a plurality of types of gas supply sources required for the etching. The flow control device group 31 includes a plurality of flow controllers, and the valve group 32 includes a plurality of valves. Each of the plurality of flow controllers of the flow control device group 31 is a mass flow controller or a pressure control type flow controller. In the etching device 1, the processing gas from one or more gas supply sources selected from the gas supply source group 30 is supplied to the gas diffusion chamber 22a via the flow control device group 31, the valve group 32, the gas supply pipe 33, and the gas introduction hole 22c. In addition, the processing gas supplied to the gas diffusion chamber 22a is distributed and supplied to a shower room in the processing space S via the gas distribution hole 22b and the gas injection hole 21a. A baffle plate 40 is provided between an inner wall of the chamber and the support member 17 as the bottom of the chamber 10. The baffle plate 40 is configured by coating an aluminum material with the ceramics such as yttrium oxide, for example. A plurality of penetration holes is formed in the baffle plate 40. The processing space S communicates with an exhaust port 41 via the baffle plate 40. For example, an exhaust device 42 such as a vacuum pump is connected to the exhaust port 41, and the inside of the processing space S is configured to be decompressed by the exhaust device 42.

Further, a loading/unloading port 43 of the wafer W is formed on a side wall of the chamber 10, and the loading/unloading port 43 is openable/closable by a gate valve 44.

As illustrated in FIGS. 1 and 2, the etching device 1 further includes the first RF power supply 50 as a source RF power supply, a second RF power supply 51 as a bias RF power supply, and a matcher 52. The first RF power supply 50 and the second RF power supply 51 are coupled to the lower electrode 12 via the matcher 52.

The first RF power supply 50 generates high-frequency power HF which is source RF power for plasma generation and supplies the high-frequency power to the lower electrode 12. The high-frequency power HF may be a frequency within a range of 27 to 100 MHz, and in one example, the high frequency HF is 40 MHz. The first RF power supply 50 is coupled to the lower electrode 12 via a first matching circuit 53. The first matching circuit 53 is a circuit for matching an output impedance of the first RF power supply 50 and an input impedance of a load side (lower electrode 12 side). Further, the first RF power supply 50 may not be electrically coupled to the lower electrode 12 and may be coupled to a shower head 20 which is an upper electrode via the first matching circuit 53. Further, instead of the first RF power supply 50, a pulse power supply may be used, which is configured to apply pulse voltage other than the high-frequency power to the lower electrode 12. The pulse power supply is similar to the pulse power supply used instead of the second RF power supply 51 to be described below.

The second RF power supply 51 generates high-frequency power LF which is bias RF power for drawing the ion to the wafer W and supplies the high-frequency power LF to the lower electrode 12. The high-frequency power LF may be a frequency within a range of 400 kHz to 13.56 MHz, and in one example, the high frequency power LF is 400 kHz. The second RF power supply 51 is coupled to the lower electrode 12 via a second matching circuit 54 of the matcher 52. The second matching circuit 54 is a circuit for matching the output impedance of the second RF power supply 51 and the input impedance of the load side (lower electrode 12 side). Further, instead of the second RF power supply 51, a pulse power supply may be used, which is configured to apply pulse voltage other than the high-frequency power to the lower electrode 12. Here, the pulse voltage is pulse-shaped voltage in which a magnitude of the voltage is periodically changed. The pulse power supply may be a DC power supply. The pulse power supply itself may be configured to apply the pulse voltage, and configured to include a device which pulses the voltage to a downstream side. In one example, the pulse voltage is applied to the lower electrode 12 so that a negative potential is generated in the wafer W. The pulse voltage may be a rectangular wave, a triangular wave, and an impulse, or may have other waveforms. The frequency (pulse frequency) of the pulse voltage may also be a frequency within a range of 100 kHz to 2 MHz. Further, the high-frequency power LF or the pulse voltage may be supplied or applied to a bias electrode provided inside the electrostatic chuck 13.

The etching device 1 further includes a first variable passive element 60 and a second variable passive element 61. The first variable passive element 60 and the second variable passive element 61 are arranged from the edge erring 14 in this order. The second variable passive element 61 is connected to the ground potential. That is, the second variable passive element 61 is not connected to each of the first RF power supply 50 and the second RF power supply 51.

In one example, in at least one of the first variable passive element 60 and the second variable passive element 61, the impedance is configured variably. The first variable passive element 60 and the second variable passive element 61 may be any one of a coil (inductor) or a condenser (capacitor), for example. Further, although is not limited to the coil and the condenser, even any variable impedance element such as an element such as a diode, etc. may achieve a similar function. The numbers or the positions of first variable passive elements 60 and second variable passive elements 61 may also be appropriately designed by those skilled in the art. Further, the element itself need not be variable, and for example, a plurality of elements in which the impedance has a fixed value is provided, and the impedance may be variable by switching a combination of the elements in which the impedance has the fixed value by using a switching circuit. Further, each of circuit configurations of the first variable passive element 60 and the second variable passive element 61 may be appropriately designed by those skilled in the art.

As illustrated in FIGS. 1, 2A, and 2B, the etching device 1 further includes a driving device 70 which moves the edge ring 14 in the vertical direction. The driving device 70 includes a lifter pin 71 which moves in the vertical direction by supporting the edge ring 14 and a driving source 72 which moves the lifter pin 71 in the vertical direction.

The lifter pin 71 extends from the lower surface of the edge ring 14 in the vertical direction, and is provided to penetrate the electrostatic chuck 13, the lower electrode 12, the support member 17, and the bottom of the chamber 10. A space between the lifter pin 71 and the chamber 10 is sealed in order to seal the inside of the chamber 10. The surface of the lifter pin 71 may be at least made of the insulating material.

The driving source 72 is provided outside the chamber 10. The driving source 72 has a motor built therein and moves the lifter pin 71 in the vertical direction. That is, by the driving device 70, the edge ring 14 is configured to be movable in the vertical direction between a state of being mounted on the electrostatic chuck 13 as illustrated in FIG. 2A and a state of being separated from the electrostatic chuck 13 as illustrated in FIG. 2B.

A controller 100 is provided in the etching device 1 described above. The controller 100 is a computer having a CPU or a memory, and has a program storage (not illustrated), for example. The program storage stores a program which controls etching in the etching device 1. Further, the program is recorded in a computer readable storage medium, and may be installed in the controller 100 from the storage medium. Further, the storage medium may be temporary or non-temporary.

<Etching Method>

Next, the etching performed by using the etching device 1 configured as above will be described.

First, the wafer W is loaded to the inside of the chamber 10, and the wafer W is mounted on the electrostatic chuck 13. Thereafter, by applying the DC voltage to the first electrode 16a of the electrostatic chuck 13, the wafer W is electrostatically adsorbed and held on the electrostatic chuck 13 by Coulomb force. Further, after the wafer W is loaded, the inside of the chamber 10 is decompressed up to a desired vacuum degree by the exhaust device 42.

Next, the processing gas is supplied from the gas supply source group 30 to the processing space S via the shower head 20. Further, the high-frequency power HF for plasma generation is supplied to the lower electrode 12 by the first RF power supply 50, and the processing gas is excited to generate plasma. In this case, the high-frequency power LF for ion insertion may be supplied by the second RF power supply 51. In addition, by an action of the generated plasma, the wafer W is etched.

When the etching is terminated, first, the supply of the high-frequency power HF from the first RF power supply and the supply of the processing gas by the gas supply source group 30 are stopped. Further, when the high-frequency power LF is supplied while etching, the supply of the high-frequency power LF is also stopped. Then, the supply of the heat transfer gas from a back surface of the wafer W is stopped and the adsorption and holding of the wafer W by the electrostatic chuck 13 are stopped.

Thereafter, the wafer W is unloaded from the chamber 10 to terminate a series of etching for the wafer W.

Further, in the etching, the plasma may also be generated by using only the high-frequency power LF from the second RF power supply 51 without using the high-frequency power HF from the first RF power supply 50.

<Tilt Angle Control Method>

Next, in the etching, a method for controlling a tilt angle will be described. The tilt angle is an inclination (angle) of the concave portion formed by etching in the thickness direction of the wafer W in the edge area of the wafer W. The tilt angle becomes almost the same angle as the inclination (incident angle of the ion) of the incident direction of the ion on the edge area of the wafer W to the vertical direction. Further, in the following description, a direction toward the inside in a diameter direction with regard to the thickness direction (vertical direction) of the wafer W is referred to as an inner side and a direction toward the outside in the diameter direction with regard to the thickness direction of the wafer W is referred to as an outer side.

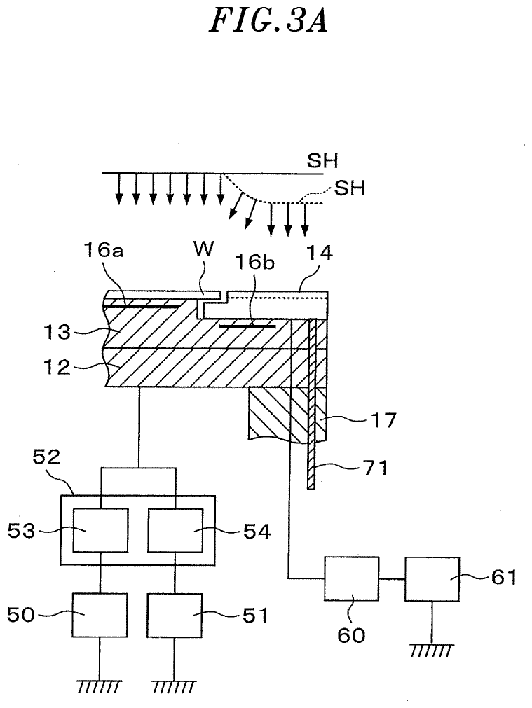

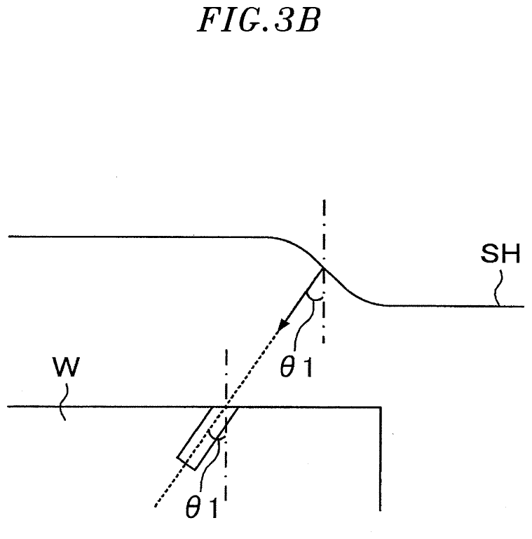

FIGS. 3A and 3B are explanatory diagrams illustrating a change in shape of a sheath due to exhaustion of the edge ring and generation of an inclination of an incident direction of an ion. In FIG. 3A, the edge ring 14 indicated by a solid line indicates the edge ring 14 in a state without the exhaustion. The edge ring 14 indicated by a dotted line indicates the edge ring 14 in which the thickness is reduced due to the exhaustion. Further, in FIG. 3A, a sheath SH indicated by the solid line indicates the shape of the sheath SH when the edge ring 14 is not exhausted. The sheath SH indicated by the dotted line indicates the shape of the sheath SH when the edge ring 14 is exhausted. Further, in FIG. 3A, an arrow indicates the incident direction of the ion when the edge ring 14 is exhausted.

As illustrated in FIG. 3A, in one example, when the edge ring 14 is not exhausted, the shape of the sheath SH is held to be flat in upper portions of the wafer W and the edge ring 14. Therefore, the ion is incident substantially in a direction perpendicular (vertical direction) to the front surface of the wafer W. Therefore, the tilt angle becomes 0 degree.

On the other hand, when the edge ring 14 is exhausted and the thickness decreases, the thickness of the sheath SH is reduced and the shape of the sheath SH is changed to a downward convex shape above the edge area of the wafer W and the edge ring 14. As a result, the incident direction of the ion on the edge area of the wafer W is inclined with respect to the vertical direction. In the following description, a phenomenon in which the concave portion formed by the etching is inclined to the inner side when the incident direction of the ion is inclined to the inside of the diameter direction (center side) in the vertical direction is called Inner Tilt. In FIG. 3B, the incident direction of the ion is inclined to the inner side at an angle θ1 and the concave portion is also inclined to the inner side at θ1. Inner Tilt can be occurred for another reasons but the exhaustion of the edge ring 14. For example, when the bias voltage generated in the edge ring 14 is lower than voltage at the wafer W side, the edge ring 14 is inner tilted in an initial state. Further, for example, in the initial state of the edge ring 14, the edge ring 14 is intentionally adjusted to be inner tilted, and there is also a case where the tilt angle is corrected by adjusting a driving amount of the driving device 70 to be described below.

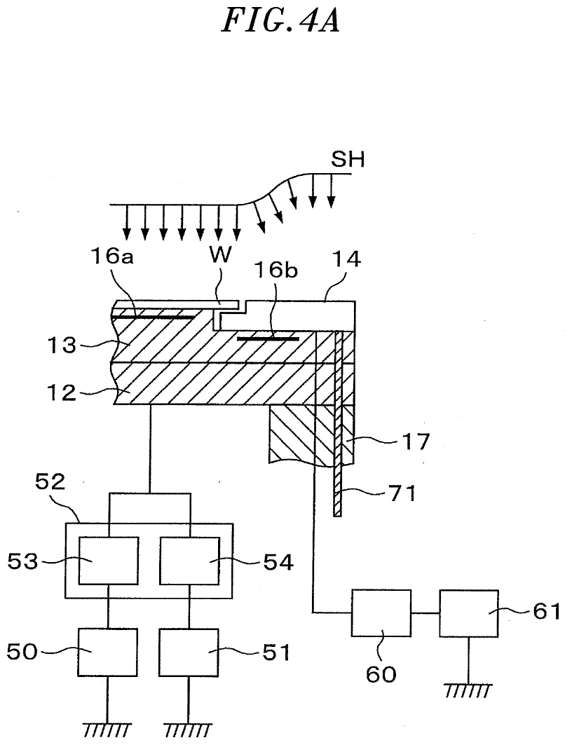

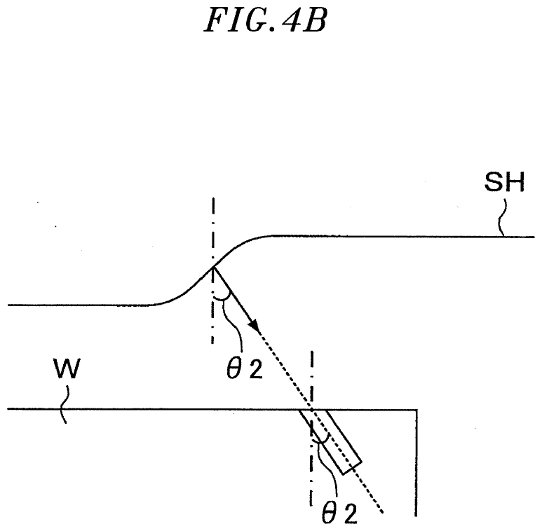

Further, as illustrated in FIGS. 4A and 4B, with respect to a center area of the wafer W, the thickness of the sheath SH may increase and the shape of the sheath SH may become an upward convex shape above the edge area of the wafer W and the edge ring 14. For example, when the bias voltage generated in the edge ring 14 is high, the shape of the sheath SH may become the upward convex shape. In FIG. 4A, the arrow indicates the incident direction of the ion. In the following description, a phenomenon in which the concave portion formed by the etching is inclined to the outer side when the incident direction of the ion is inclined to the outside of the diameter direction in the vertical direction is called Outer Tilt. In FIG. 4B, the incident direction of the ion is inclined to the outer side at an angle θ2 and the concave portion is also inclined to the outer side at θ2.

In the etching device 1 of the present embodiment, the tilt angle is controlled. Specifically, the tilt angle is at least controlled by controlling the incident angle of the ion by adjusting a driving amount (a driving amount of the edge ring 14) of the driving source 72 of the driving device 70 or the impedance of the second variable passive element 61. Further, in the following embodiment, a case of adjusting the impedance of the second variable passive element 61 is described, but the impedance of the first variable passive element 60 may be adjusted and the impedances of both variable passive elements 60 and 61 may be adjusted.

[Adjustment of Driving Amount]

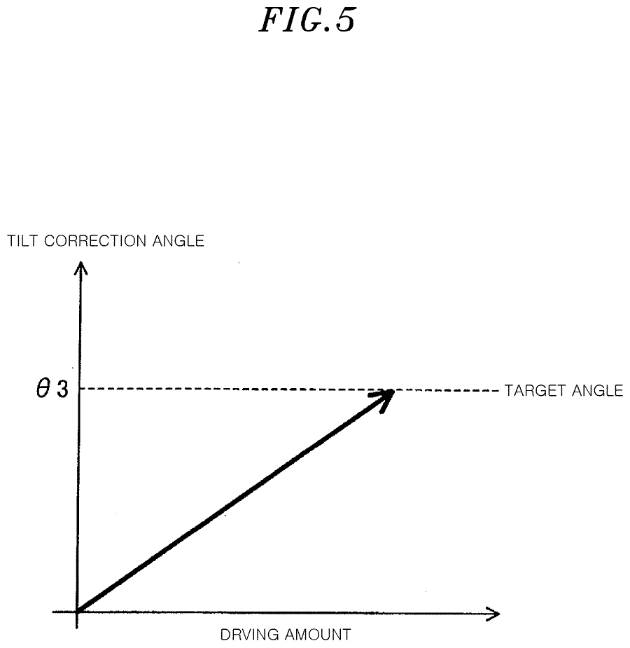

First, the case of adjusting the driving amount of the driving device 70 is described. FIG. 5 is an explanatory diagram illustrating a relationship between the driving amount of the driving device 70 and a correction angle (hereinafter, referred to as “tilt correction angle”) of the tilt angle. A vertical axis of FIG. 5 indicates the tilt correction angle and a horizontal axis indicates the driving amount of the driving device 70. As illustrated in FIG. 5, when the driving amount of the driving device 70 increases, the tilt correction angle increases.

The controller 100 sets the driving amount of the driving device 70 from an exhaustion amount (a reduction amount from an initial value of the thickness of the edge ring 14) of the edge ring 14 estimated from a process condition (e.g., a processing time) of the etching by using a predetermined function or table, for example. That is, the controller 100 determines the driving amount of the driving device 70 by inputting the exhaustion amount of the edge ring 14 into the function or by referring to the table by using the exhaustion amount of the edge ring 14.

Further, the exhaustion amount of the edge ring 14 may be estimated based on a change in etching time of the wafer W, the number of processed sheets of the wafer W, thickness of the edge ring 14 measured by a measurer, and mass of the edge ring 14 measured by the measurer, a change in electrical characteristic (e.g., a voltage value and a current value at a predetermined point around the edge ring 14) around the edge ring 14 measured by the measurer, or a change in electrical characteristic (e.g., a resistance value of the edge ring 14) of the edge ring 14 measured by the measurer. Further, the driving amount of the driving device 70 may be increased according to the etching time of the wafer W or the number of processed sheets of the wafer W regardless of the exhaustion amount of the edge ring 14. Further, the driving amount of the driving device 70 may be increased according to the etching time of the wafer W or the number of processed sheets of the wafer W to which a weight is granted by the high-frequency power.

A specific method for controlling the tilt angle by adjusting the driving amount of the driving device 70 as described above will be described. First, the edge ring 14 is installed on the electrostatic chuck 13. In this case, for example, the sheath shape is flat and the tilt angle becomes 0 degree above the edge area of the wafer W and the edge ring 14.

Next, the wafer W is etched. As a time for which the etching is performed elapses, the edge ring 14 is exhausted and the thickness of the edge ring 14 is reduced. Then, as illustrated in FIG. 3A, the thickness of the sheath SH decreases and the tilt angle is changed to the inner side above the edge area of the wafer W and the edge ring 14. Therefore, the driving amount of the driving device 70 is adjusted. Specifically, according to the exhaustion amount of the edge ring 14, the edge ring 14 is raised by increasing the driving amount of the driving device 70. Then, as illustrated in FIG. 5, the tilt correction angle may be increased and the tilt angle inclined to the inner side may be changed to the outer side. That is, the shape of the sheath above the edge ring 14 and the edge area of the wafer W is controlled, and as a result, the incident direction of the ion on the edge area of the wafer W is reduced and the tilt angle is controlled. In addition, when the edge ring 14 is raised based on the driving amount set in the controller 100 as described above, the tilt correction angle is adjusted to at a target angle θ3 to adjust the tilt angle to 0 degree. As a result, throughout an entire area of the wafer W, the concave portion which is substantially parallel to the thickness direction of the wafer W is formed.

[Adjustment of Impedance]

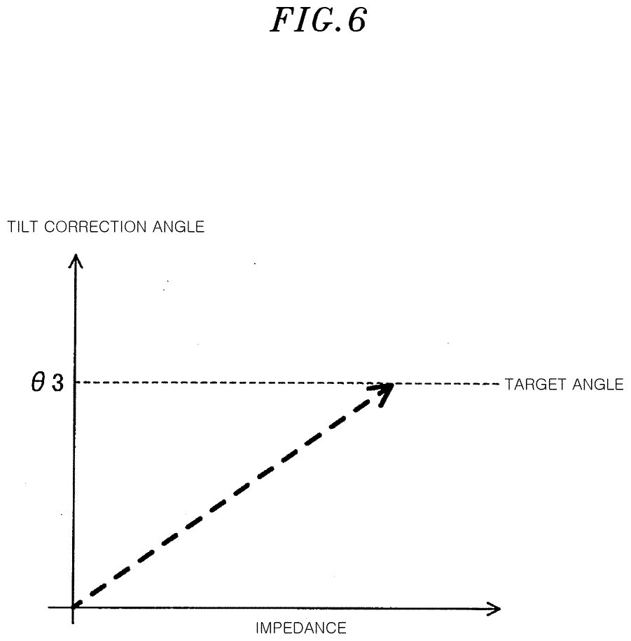

Next, the case of adjusting the impedance of the second variable passive element 61 will be described. FIG. 6 is an explanatory diagram illustrating the relationship between the impedance of the second variable passive element 61 and the tilt correction angle. The vertical axis of FIG. 6 indicates the tilt correction angle and the horizontal axis indicates the impedance of the second variable passive element 61. As illustrated in FIG. 6, when the impedance of the second variable passive element 61 increases, the tilt correction angle increases. Further, in an example illustrated in FIG. 6, the tilt correction angle increases by increasing the impedance, but it is also possible to decrease the tilt correction angle by increasing the impedance according to the configuration of the second variable passive element 61. Since the relationship between the impedance and the tilt correction angle depends on the design of the second variable passive element 61, the relationship is not limited.

The controller 100 sets the impedance of the second variable passive element 61 from the exhaustion amount of the edge ring 14 similarly to the setting of the driving amount of the driving device 70. In addition, the controller 100 changes the voltage generated in the edge ring 14 by changing the impedance of the second variable passive element 61.

In the etching device 1, when the edge ring 14 is exhausted, the second variable passive element 61 is controlled by the impedance set by the controller 100. As a result, the shape of the sheath above the edge ring 14 and the edge area of the wafer W is controlled, and as a result, the incident direction of the ion on the edge area of the wafer W is reduced and the tilt angle is controlled. Then, as illustrated in FIG. 6, the tilt angle may be set to 0 degree by adjusting the tilt correction angle to the target angle θ3.

[Adjustment of Driving Amount and Impedance]

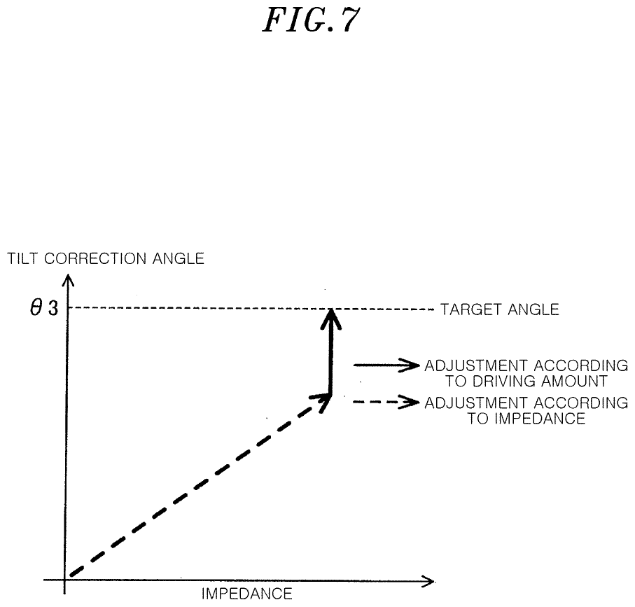

Next, a case of combining and adjusting the driving amount of the driving device 70 and the impedance of the second variable passive element 61 will be described. FIG. 7 is an explanatory diagram illustrating the relationship among the driving amount of the driving device 70, the impedance of the second variable passive element 61, and the tilt correction angle. The vertical axis of FIG. 7 indicates the tilt correction angle and the horizontal axis indicates the impedance of the second variable passive element 61.

As illustrated in FIG. 7, first, the impedance of the second variable passive element 61 is adjusted and the tilt angle is corrected. Next, when the impedance reaches a predetermined value, e.g., an upper limit value, the driving amount of the driving device 70 is adjusted and the tilt correction angle is adjusted to the target angle θ3 to set the tilt angle to 0 degree. In this case, the numbers of times of the adjustment of the impedance and the adjustment of the driving amount may be reduced and an operation of the tilt angle control may be simplified.

Here, a resolution of the tilt angle correction by the adjustment of the impedance and the resolution of the tile angle correction by the adjustment of the driving amount depend on performances of the second variable passive element 61 and the driving device 70, respectively. The resolution of the tilt angle correction is a correction amount of the tilt angle in one adjustment of the impedance or the driving amount. In addition, for example, when the resolution of the second variable passive element 61 is higher than the resolution of the driving device 70, the tilt angle is corrected by adjusting the impedance of the second variable passive element 61 in the present embodiment to enhance the resolution of the tilt angle correction as a whole.

As described above, according to the present embodiment, an adjustment range of the tilt angle may be increased by performing the adjustment of the impedance of the second variable passive element 61 and the adjustment of the driving amount of the driving device 70. Therefore, the tilt angle may be appropriately controlled, that is, the incident direction of the ion may be appropriately adjusted to evenly perform the etching.

Further, for example, when the tilt angle is intended to be controlled only by the impedance of the second variable passive element 61, if the impedance reaches an upper limit of the control range of the variable passive element 61, the edge ring 14 needs to be replaced. In this regard, in the present embodiment, the driving amount of the driving device 70 is adjusted to increase the adjustment range of the tilt angel without replacing the edge ring 14. Therefore, a replacement interval of the edge ring 14 is increased to suppress a replacement frequency of the edge ring 14.

Further, according to the present embodiment, the resolution of the tilt angle correction may be enhanced while simplifying the operation of the tilt angle control. In addition, modification of the operation of the tilt angle control may be increased.

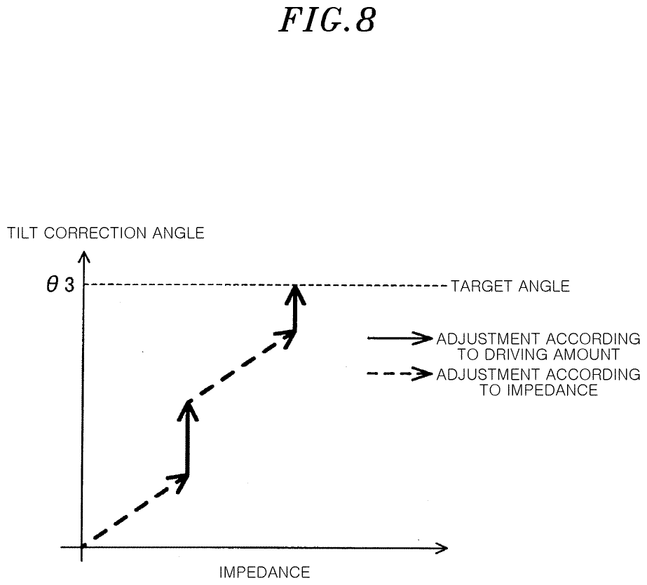

Further, in an example illustrated in FIG. 7, each of the adjustment of the impedance and the adjustment of the driving amount is performed at one time to adjust the tilt correction angle to the target angle θ3, but the numbers of times of the adjustment of the impedance and the adjustment of the driving amount are not limited thereto. For example, as illustrated in FIG. 8, each of the adjustment of the impedance and the adjustment of the driving amount may be performed multiple times. Even in this case, the same effect as the present embodiment may be enjoyed.

Further, in the examples illustrated in FIGS. 7 and 8, after the adjustment of the impedance of the second variable passive element 61 is performed, the adjustment of the driving amount of the driving device 70 is performed, but this order may be opposite. In this case, first, the driving amount of the driving device 70 is adjusted and the tilt angle is corrected. In this case, when the driving amount of the driving device 70 excessively increased, discharge occurs between the wafer W and the edge ring 14. Therefore, there is a limit in the driving amount of the driving device 70. Therefore, next, when the driving amount reaches a predetermined value, e.g., an upper limit value, the impedance of the second variable passive element 61 is adjusted and the tilt correction angle is adjusted to the target angle 83 to set the tilt angle to 0 degree. Even in this case, the same effect as the present embodiment may be enjoyed.

Further, in the above embodiment, the adjustment of the impedance of the second variable passive element 61 and the adjustment of the driving amount of the driving device 70 are separately performed, but the adjustment of the impedance and the adjustment of the driving amount may be simultaneously performed.

### Other Embodiments

Here, as described above, the frequency of the high-frequency power (bias RF power) LF supplied from the second RF power supply 51 is 400 kHz to 13.56 MHz, but the frequency is more preferably 5 MHz or less. When the etching is performed, in the case of performing etching of a high aspect ratio for the wafer W, high ion energy is required to realize a vertical shape of a pattern after etching. Therefore, as a result of hard reviewing by the present inventors, by setting the frequency of the high-frequency power LF to 5 MHz or less, which increases the track of the ion for the change in high-frequency electric field, and enhances controllability of ion energy.

Meanwhile, there is a case in which the impedance of the second variable passive element 61 is variable by adjusting the frequency of the high-frequency power LF to a low frequency of 5 MHz or less. That is, there is a case in which the controllability of the tilt angle by adjusting the impedance of the second variable passive element 61 deteriorates. For example, in FIGS. 2A and 2b, when an electrical connection of the edge ring 14 and the second variable passive element 61 is non-contact or capacitive coupling, the tilt angle may not be appropriately controlled in spite of adjusting the impedance of the second variable passive element 61. Therefore, in the present embodiment, the edge ring 14 and the second variable passive element 61 are electrically directly connected.

The edge ring 14 and the second variable passive element 61 are electrically directly connected via the connector. The edge ring 14 and the connector are in contact with each other, and DC current is conducted on the connector. Hereinafter, one example of a structure (hereinafter, may be referred to as “contact structure”) of the connector will be described.

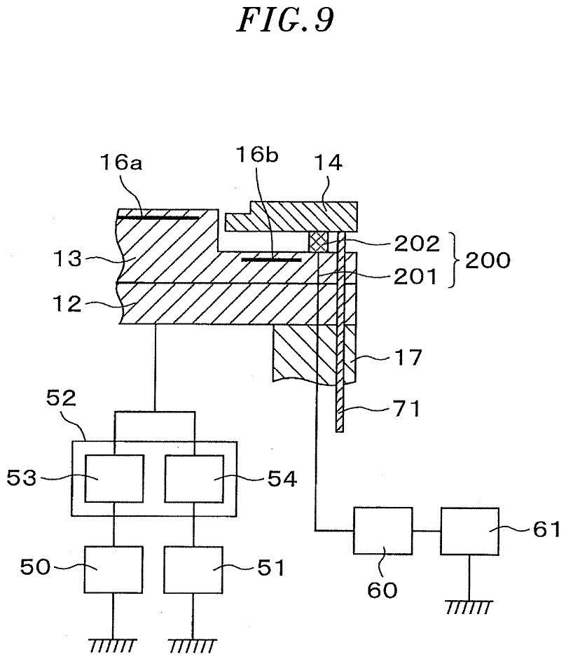

As illustrated in FIG. 9, the connector 200 as a conductor has a conductive structure 201 and a conductive elastic member 202. The conductive structure 201 connects the edge ring 14 and the second variable passive element 61 via the conductive elastic member 202. Specifically, one end is connected to the second variable passive element 61 and the other end is exposed on the upper surface of the lower electrode 12, and the conductive structure 201 is in contact with the conductive elastic member 202.

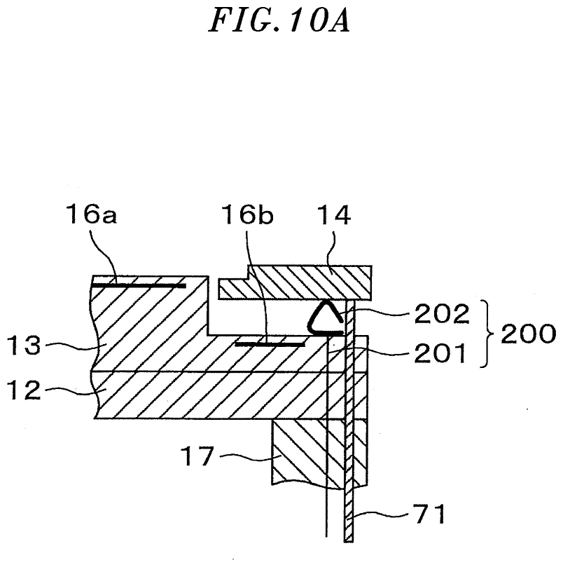

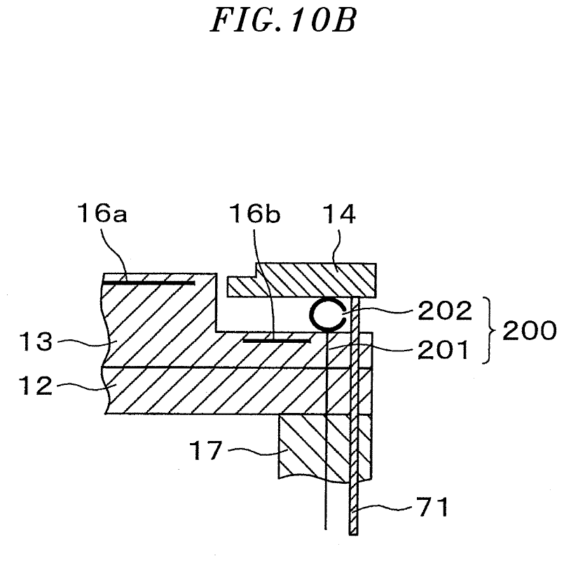

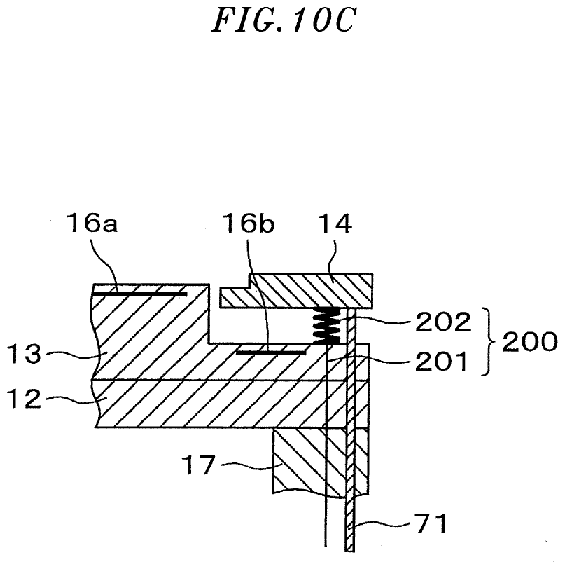

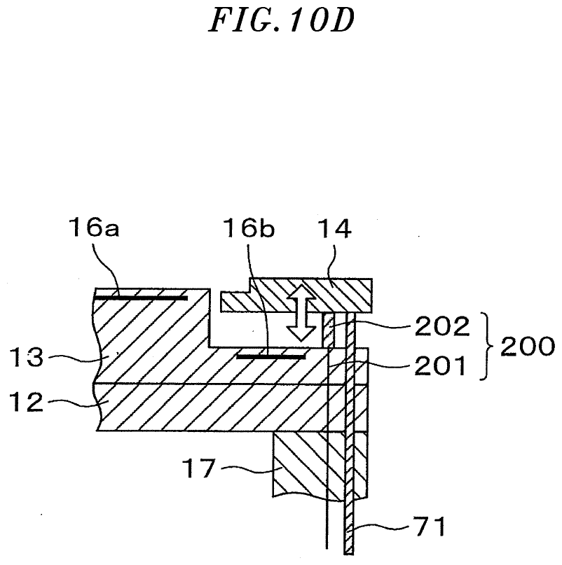

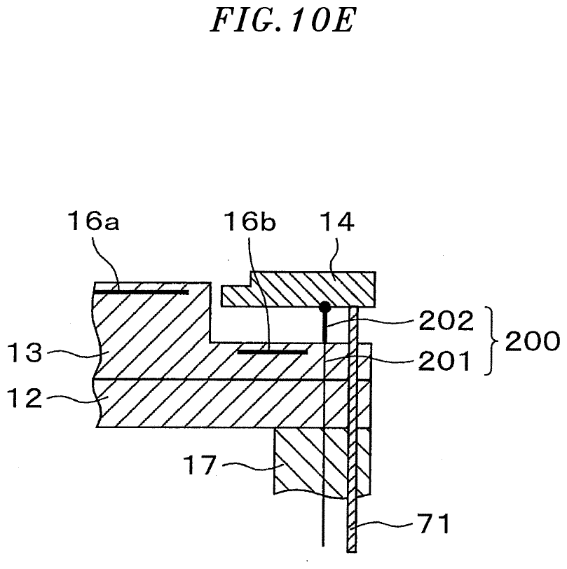

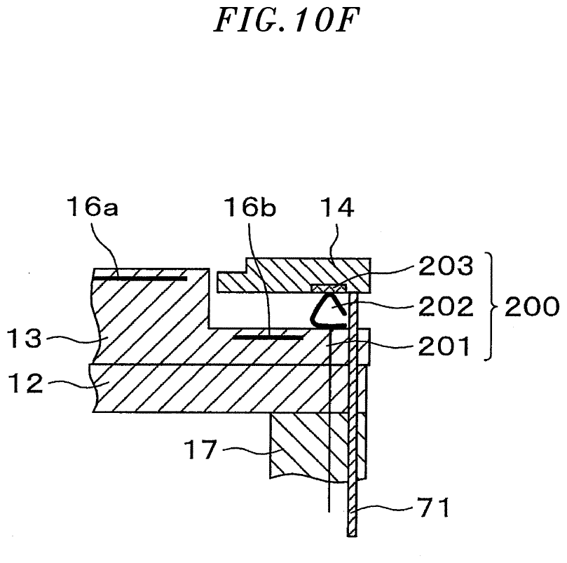

The conductive elastic member 202 is provided in a space formed between the edge ring 14 and the electrostatic chuck 13, for example. The conductive elastic member 202 is in contact with each of the conductive structure 201 and the lower surface of the edge ring 14. Further, the conductive elastic member 202 is made of a conductor such as metal. The configuration of the conductive elastic member 202 is not particularly limited, but each of FIGS. 10A to 10F illustrates one example. Further, FIGS. 10A to 10C illustrate an example of using an elastic body as the conductive elastic member 202.

As illustrated in FIG. 10A, a plate spring to which force is applied in the vertical direction may be used as the conductive elastic member 202. As illustrated in FIG. 10B, a coil spring which is wound in a spiral shape and extends in the horizontal direction may be used as the conductive elastic member 202. As illustrated in FIG. 10C, a spring which is wound in the spiral shape and extends in the vertical direction may be used as the conductive elastic member 202. In addition, the conductive elastic members 202 are elastic bodies, and elastic force acts on the conductive elastic members 202 in the vertical direction. By the elastic force, the conductive elastic member 202 is in close contact with each of the conductive structure 201 and the lower surface of the edge ring 14 with desired contact pressure, and the conductive structure 201 and the edge ring 14 are electrically connected.

As illustrated in FIG. 10D, a pin which moves in the vertical direction by a driving mechanism (not illustrated) may be used as the conductive elastic member 202. In this case, the conductive elastic member 202 is raised, so the conductive elastic member 202 is in contact with each of the conductive structure 201 and the lower surface of the edge ring 14. In addition, pressure which acts in vertical movement of the conductive elastic member 202 is adjusted, so the conductive elastic member 202 is in contact with each of the conductive structure 201 and the lower surface of the edge ring 14 with desired contact pressure.

As illustrated in FIG. 10E, a wire which connects the conductive structure 201 and the edge ring 14 may be used as the conductive elastic member 202. One end of the wire is bonded to the conductive structure 201 and the other end is bonded to the lower surface of the edge ring 14. The bonding of the wire may be ohmic contact with the conductive structure 201 or the lower surface of the edge ring 14, and as one example, the wire is welded or pressed. In addition, when the wire is used as the conductive elastic member 202 as such, the conductive elastic member 202 is in close contact with each of the conductive structure 201 and the lower surface of the edge ring 14, and the conductive structure 201 and the edge ring 14 are electrically connected.

Hereinabove, even when any conductive elastic member 202 illustrated in FIGS. 10A to 10E is used, the edge ring 14 and the second variable passive element 61 may be electrically directly connected via the connector 200 as illustrated in FIG. 9. Therefore, the frequency of the high-frequency power LF may be set to a low frequency of 5 MHz or less, and the controllability of the ion energy may be enhanced.

Further, when the tilt angle is controlled by adjusting the driving amount of the driving device 70, the connector 200 is provided to suppress the adjusted driving amount to be reduced. As a result, discharge may be suppressed between the wafer W and the edge ring 14. Further, as described above, the adjustment range of the tilt angle is increased by adjusting the driving amount of the driving device 70 and the impedance of the second variable passive element 61 to control the tilt angle to a desired value.

Further, in the above embodiment, as the conductive elastic member 202, the plate spring illustrated in FIG. 10A, the coil spring illustrated in FIG. 10B, the spring illustrated in FIG. 10C, the pin illustrated in FIG. 10D, and the wire illustrated in FIG. 10E are exemplified, but these may be combined and used.

Further, in the connector 200 of the above embodiment, a conductive membrane 203 may be provided between the conductive elastic member 202 and the conductive elastic member 202 of the connector 200 and the edge ring 14 as illustrated in FIG. 10F. As the conductive membrane 203, for example, a metallic membrane is used. The conductive membrane 203 is at least provided at a portion contacting the conductive elastic member 202 on the lower surface of the edge ring 14. The conductive membrane 203 may be provided on the front surface of the lower surface of the edge ring 14 or a plurality of conductive membranes 203 may be provided in a shape close to a ring shape as a whole. Even in any case, by the conductive membrane 203, resistance by the contact of the conductive elastic member 202 may be suppressed, and the edge ring 14 and the second variable passive element 61 may be appropriately connected.

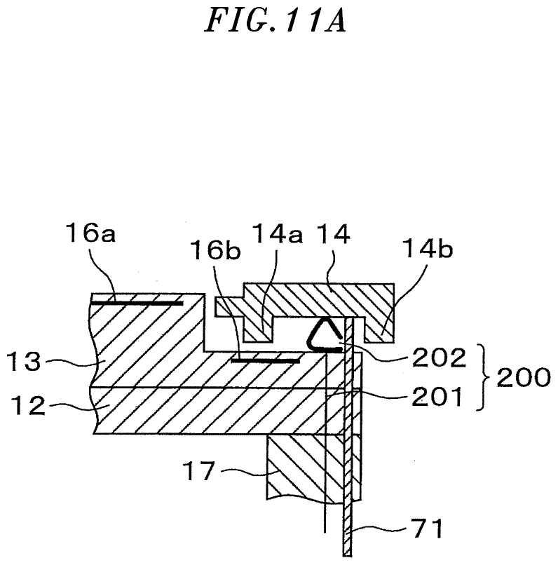

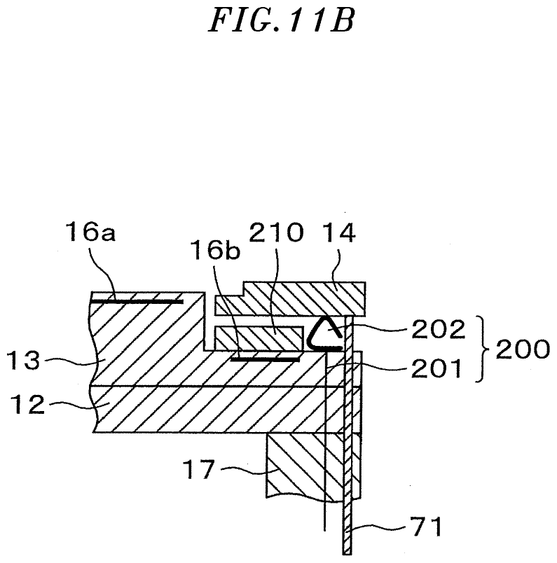

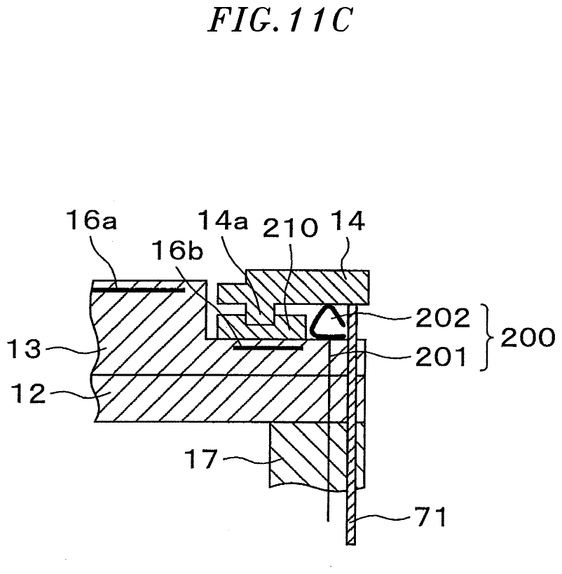

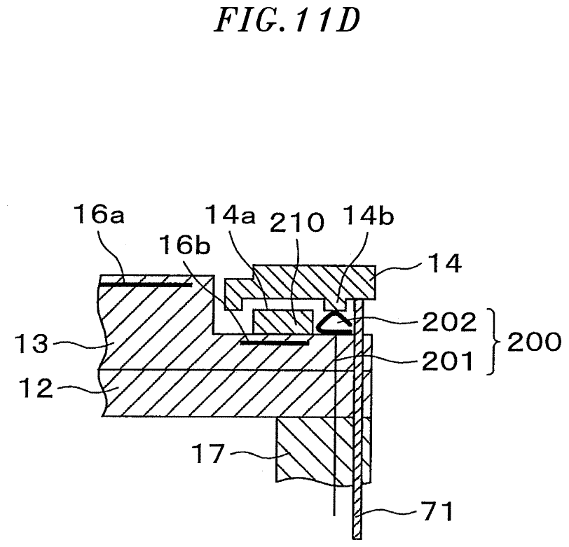

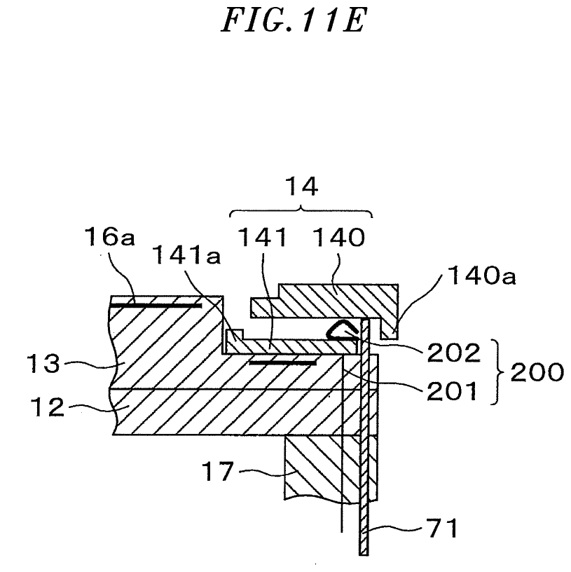

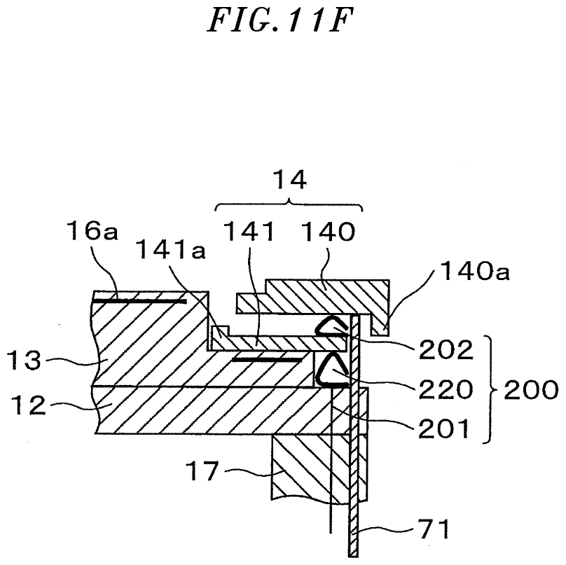

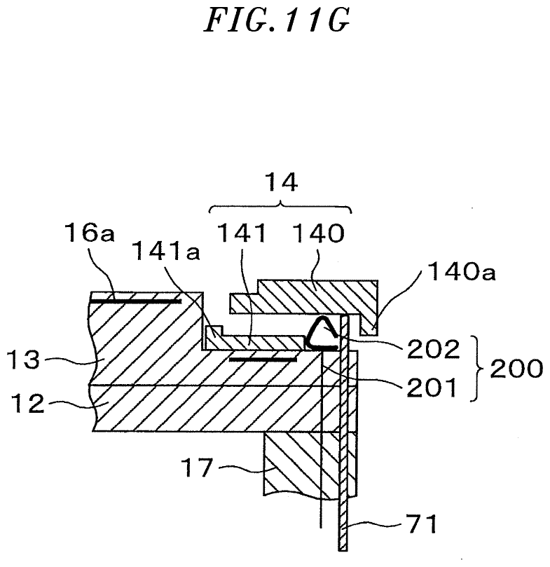

The connector 200 of the above embodiment preferably has a configuration in which the conductive elastic member 202 is protected from the plasma when the edge ring 14 is raised by the driving device 70. Each of FIGS. 11A to 11G illustrates one example of a plasma countermeasure of the conductive elastic member 202.

Protrusions 14a and 14b which protrude downward on the lower surface may be provided on the lower surface of the edge ring 14 as illustrated in FIG. 11A. In the illustrated example, the protrusion 14a is provided inside the diameter direction of the conductive elastic member 202 and the protrusion 14b is provided outside the diameter direction of the conductive elastic member 202. That is, the conductive elastic member 202 is provided at concave portions formed as the protrusions 14a and 14b. In this case, by the protrusions 14a and 14b, the plasma may be suppressed from turning into the conductive elastic member 202, and the conductive elastic member 202 may be protected.

Further, in the example of FIG. 11A, the protrusions 14a and 14b are provided on the lower surface of the edge ring 14, but the shape of suppressing the plasma from turning into the conductive elastic member 202 is not limited thereto, and may be determined according to the etching device 1. Further, the shape of the edge ring 14 may be determined so that the edge ring 14 may appropriately move in the vertical direction by the driving device 70.

As illustrated in FIG. 11B, an additional edge ring 210 may be provided inside the conductive elastic member 202 between the edge ring 14 and the electrostatic chuck 13. The additional edge ring 210 is made of the insulating material. The additional edge ring 210 is provided separately from the lower electrode 12, and for example, has a circular ring shape. In this case, by the additional edge ring 210, the plasma may be suppressed from turning into the conductive elastic member 202, and the conductive elastic member 202 may be protected.

As illustrated in FIG. 11C, both the protrusion 14a of the edge ring 14 illustrated in FIG. 11A and the additional edge ring 210 illustrated in FIG. 11B may be provided. In this case, by the protrusion 14a and the additional edge ring 210, the plasma may be further suppressed from turning into the conductive elastic member 202, and the conductive elastic member 202 may be protected.

As illustrated in FIG. 11D, both the protrusions 14a and 14b of the edge ring 14 illustrated in FIG. 11A and the additional edge ring 210 illustrated in FIG. 11B may be provided. The conductive elastic member 202 is in contact with the protrusion 14b. Further, the additional edge ring 210 is provided between the protrusions 14a and 14b. In this case, a mirror structure may be formed by the protrusions 14a and 14b and the additional edge ring 210, the plasma may be further suppressed from turning into the conductive elastic member 202, and the conductive elastic member 202 may be protected.

As illustrated in FIG. 11E, the edge ring 14 may be divided into an upper edge ring 140 and a lower edge ring 141. The upper edge ring 140 corresponds to the edge ring in the present disclosure and the lower edge ring 141 corresponds to the additional edge ring in the present disclosure. The upper edge ring 140 is configured to be movable in the vertical direction by the driving device 70. The lower edge ring 141 does not move in the vertical direction. The conductive elastic member 202 is provided in contact with the lower surface of the upper edge ring 140 and the upper surface of the lower edge ring 141. The conductive structure 201 is connected to the lower edge ring 141. In this case, the upper edge ring 140 and the second variable passive element 61 are electrically connected via the conductive elastic member 202, the lower edge ring 141, and the conductive structure 201.

A protrusion 140a which protrudes downward on the lower surface is provided on an outermost circumferential portion of the lower surface of the upper edge ring 140. A protrusion 141a which protrudes upward on the upper surface is provided on an innermost circumferential portion of the upper surface of the upper edge ring 141. In this case, by the protrusions 140a and 141a, the plasma may be suppressed from turning into the conductive elastic member 202, and the conductive elastic member 202 may be protected.

FIG. 11F is a modified example of FIG. 11E. In the example illustrated in FIG. 11E, the conductive structure 201 is connected to the lower edge ring 141, but in an example illustrated in FIG. 11F, one end of the conductive structure 201 is exposed on the upper surface of the lower electrode 12 and is in contact with the conductive elastic member 220. The conductive elastic member 220 is provided in a space formed between the lower surface of the lower edge ring 141 and the upper surface of the lower electrode 12 outside the diameter direction of the electrostatic chuck 13. That is, the conductive elastic member 220 is in contact with the lower surface of the lower edge ring 141 and the conductive structure 201. In this case, the upper edge ring 140 and the second variable passive element 61 are electrically connected via the conductive elastic member 202, the lower edge ring 141, the conductive elastic member 220, and the conductive structure 201. In addition, even in the example, by the protrusions 140a and 141a, the plasma may be suppressed from turning into the conductive elastic member 202, and the conductive elastic member 202 may be protected.

FIG. 11G is a modified example of FIG. 11E. In the example illustrated in FIG. 11E, the conductive elastic member 202 is provided on the upper surface of the lower edge ring 141, but in an example illustrated in FIG. 11G, the conductive elastic member 202 is provided on the upper surface of the lower electrode 12. The conductive elastic member 202 is in contact with the lower surface of the upper edge ring 140 and the conductive structure 201. One end of the conductive structure 201 is exposed on the upper surface of the electrostatic chuck 13, and is in contact with the conductive elastic member 202. In this case, the upper edge ring 140 and the second variable passive element 61 are electrically connected via the conductive elastic member 202 and the conductive structure 201. In addition, even in the example, by the protrusions 140a and 141a, the plasma may be suppressed from turning into the conductive elastic member 202, and the conductive elastic member 202 may be protected.

Further, in the above embodiment, the configurations illustrated in FIGS. 11A to 11G may be combined and used. Further, in the connector 200, plasma-resistance coating may be performed for a portion on the surface of the conductive elastic member 202 other than a portion contacting the edge ring 14. In this case, the conductive elastic member 202 may be protected from the plasma.

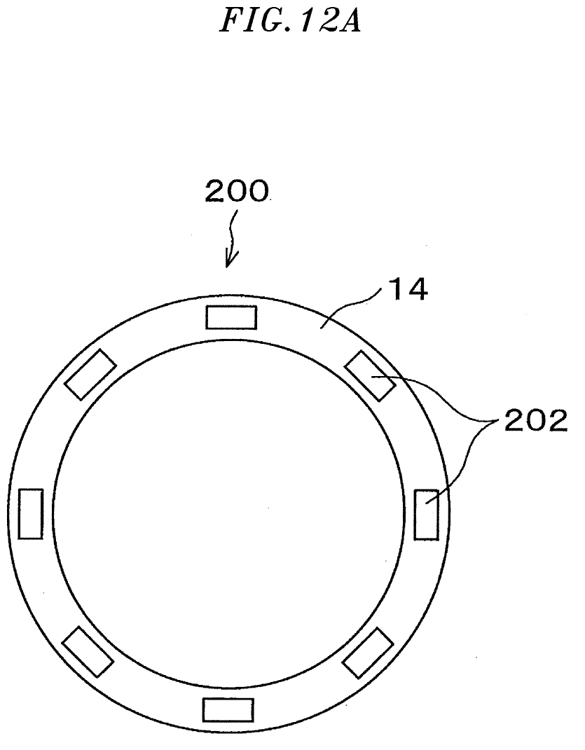

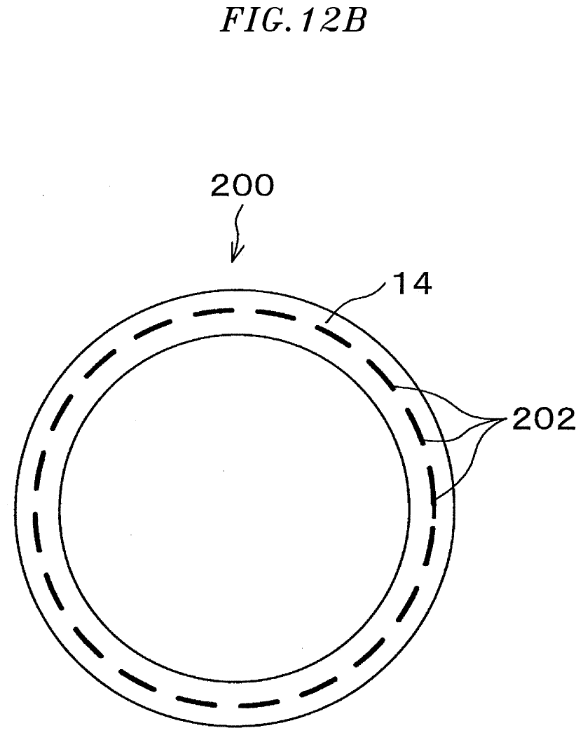

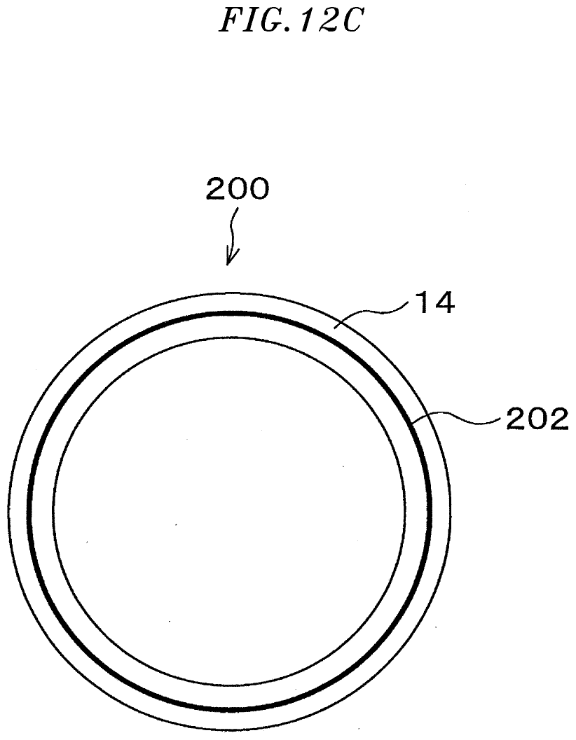

Next, a layout of the conductive elastic member 202 in a plan view will be described. Each of FIGS. 12A to 12C illustrates one example of a plane layout of the conductive elastic member 202. As illustrated in FIGS. 12A and 12B, the connector 200 may include a plurality of conductive elastic members 202, and the plurality of conductive elastic members 202 may be provided on a concentric circle with the edge ring 14 at an equal interval. In the example of FIG. 12A, the conductive elastic members 202 are provided at 8 places and in FIG. 12B, the conductive elastic members 202 are provided at 24 places. Further, as illustrated in FIG. 12C, the conductive elastic member 202 may be provided in the ring shape on the concentric circle with the edge ring 14.

From a viewpoint of etching uniformly and making the shape of the sheath uniformly (process uniformization viewpoint), as illustrated in FIG. 12C, it is preferable to provide the conductive elastic member 202 in the ring shape for the edge ring 14, and to uniformly perform the contact with the edge ring 14 on a circumference. Further, similarly, from the process uniformization viewpoint, even when the plurality of elastic conductive members 202 is provided as illustrated in FIGS. 12A and 12B, it is preferable to arrange the plurality of conductive elastic members 202 at an equal interval in a circumferential direction of the edge ring 14 and to provide a contact point with the edge ring 14 at a point symmetry. In other words, as compared with the example of FIG. 12A, it is preferable that by increasing the number of conductive elastic members 202 as in the example of FIG. 12B, the conductive elastic members 202 are close to the ring shape as illustrated in FIG. 12C. Further, the number of conductive elastic members 202 is not particularly limited, but three or more are preferable, e.g., 3 to 36 conductive elastic members 202 may be provided in order to secure the symmetry.

However, in order to avoid interference with other members due to the device configuration, it may be difficult that the conductive elastic member 202 is formed in the ring shape or the number of conductive elastic members 202 is increased. Therefore, the plane layout of the conductive elastic member 202 may be appropriately set by considering a condition of process uniformization or a constraint on the device configuration.

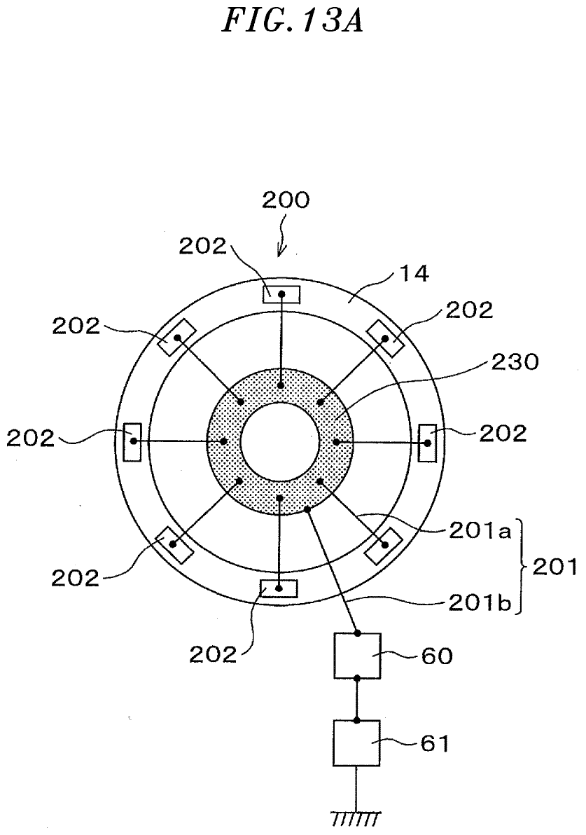

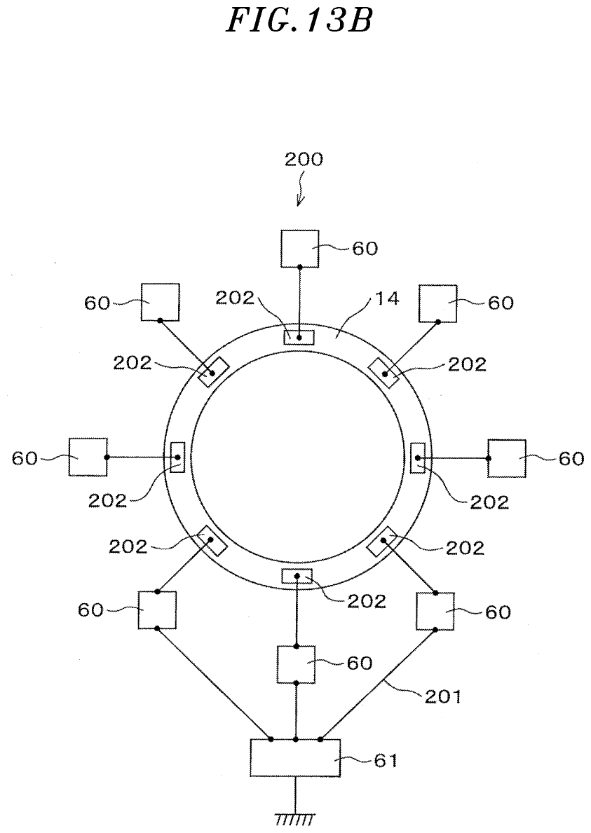

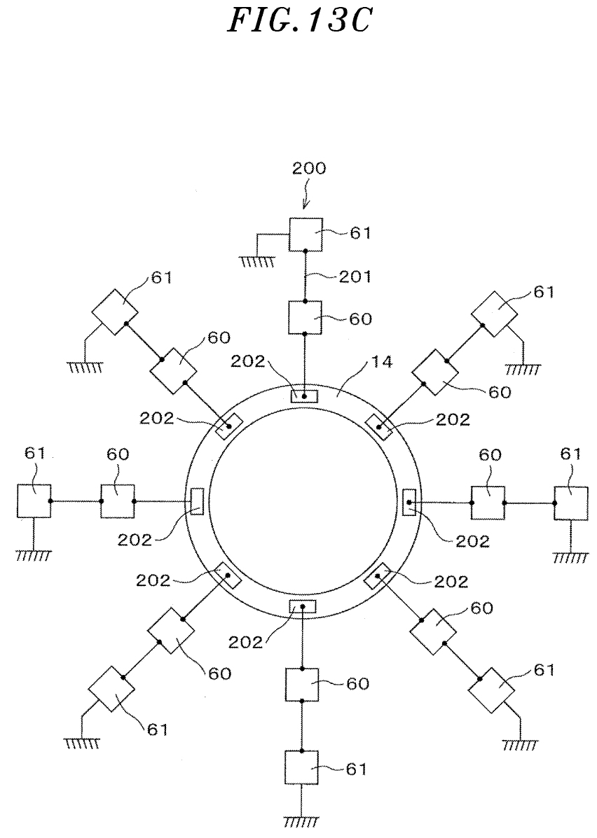

Next, the relationship of the connector 200, the first variable passive element 60, and the second variable passive element 61 will be described. Each of FIGS. 13A to 13C schematically illustrates one example of the configuration of the connector 200, the first variable passive element 60, and the second variable passive element 61.

As illustrated in FIG. 13A, for example, when one first variable passive element 60 and one second variable passive element 61 are each provided with respect to 8 conductive elastic members 202, the connector 200 may further include a relay member 230. Further, in FIG. 13A, a case where the relay member 230 is provided in the connector 200 illustrated in FIG. 12A is illustrated, but the relay member 230 may be provided even in the connector 200 illustrated in any one of FIG. 12B or 12C. Further, a plurality of relay members 230 may be provided.

The relay member 230 is provided in the ring shape on the concentric circle with the edge ring 14 in the conductive structure 201 between the conductive elastic member 202 and the second variable passive element 61. The relay member 230 is connected to the conductive elastic member 202 and a conductive structure 201a. That is, 8 conductive structures 201a is extended radially from the relay member 230 on the plan view, and connected to 8 conductive elastic members 202, respectively. Further, the relay member 230 is connected to the second variable passive element 61 and a conductive structure 201b via the first variable passive element 60.

In this case, for example, even though the second variable passive element 61 is not disposed at the center of the edge ring 14, the electrical characteristics (predetermined voltage and current values) in the relay member 230 may be performed uniformly on the circumference, and the electrical characteristics for each of 8 conductive elastic members 202 may be uniform. As a result, the etching may be performed uniformly, and the shape of the sheath may be uniform.

As illustrated in FIG. 13B, for example, a plurality of first variable passive elements 60, e.g., 8 first variable passive elements 660 may be provided, and one second variable passive element 61 may be provided for 8 conductive elastic members 202. The number of first variable passive elements 60 may be appropriately set with respect to the number of conductive elastic member 202 as described above. Further, even in the example of FIG. 13B, the relay member 230 may be provided.

As illustrated in FIG. 13C, for example, a plurality of first variable passive elements 60, e.g., 8 first variable passive elements 660 may be provided, and a plurality of, e.g., 8 second variable passive elements 61 may be provided for 8 conductive elastic members 202. The number of second variable passive elements 61 in which the impedance is variable may be appropriately set with respect to the number of conductive elastic member 202 as described above. Further, even in the example of FIG. 13C, the relay member 230 may be provided.

Further, the plurality of second variable passive elements 61 in which the impedance is variable is provided to individually independently control the electrical characteristics for the plurality of conductive elastic members 202. As a result, the electrical characteristics for each of the plurality of conductive elastic members 202 may be uniform and the uniformity of the process may be enhanced.

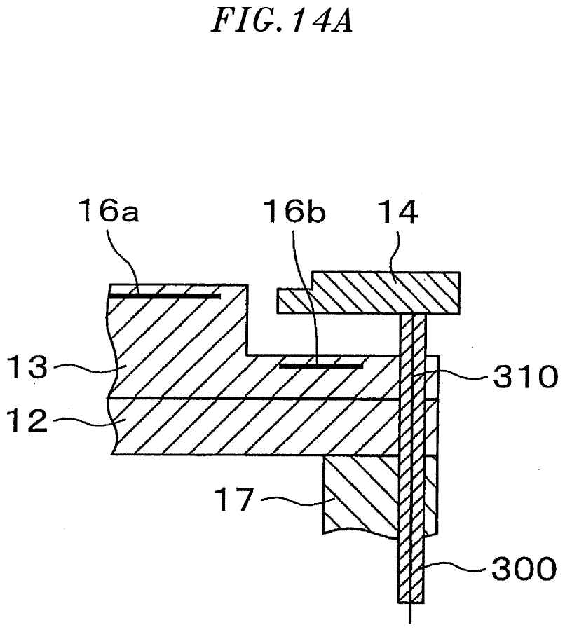

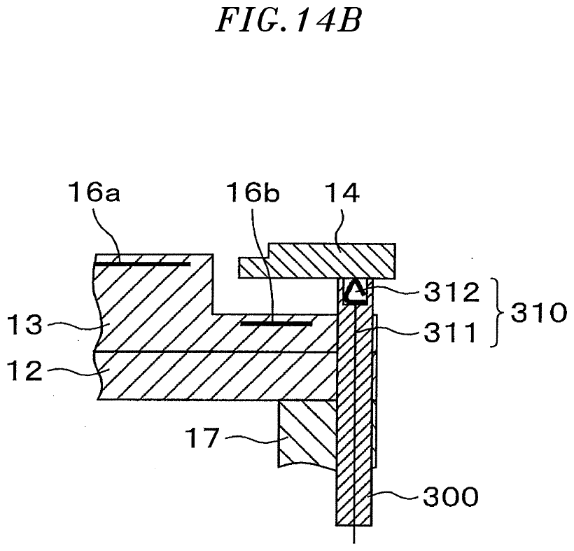

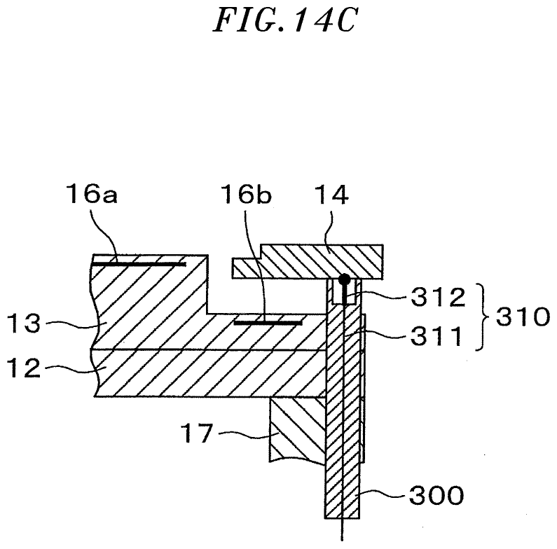

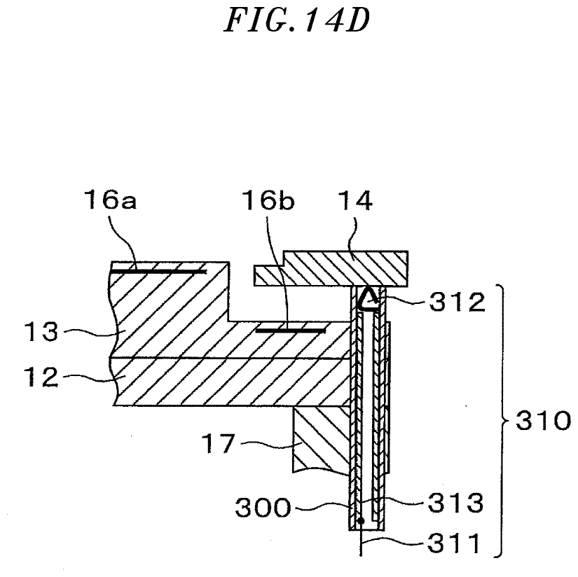

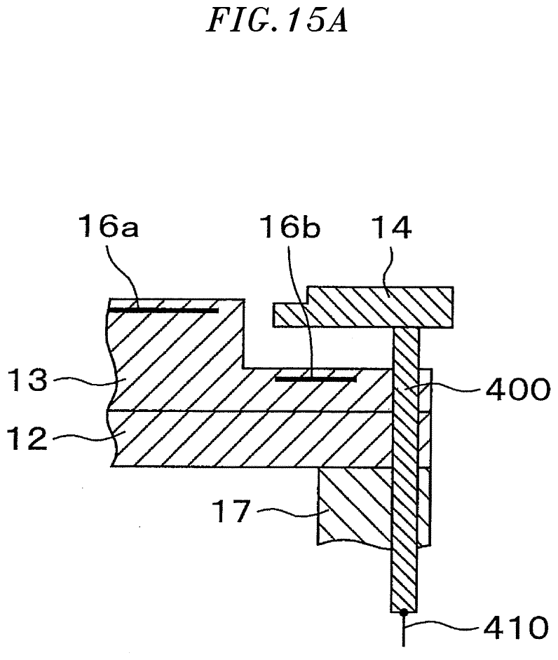

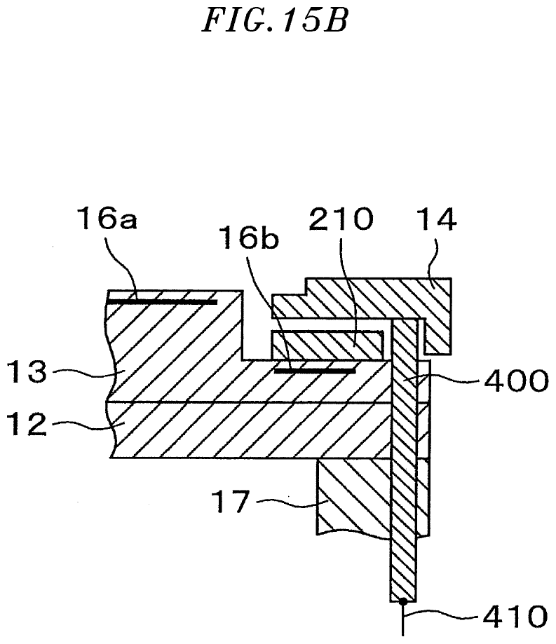

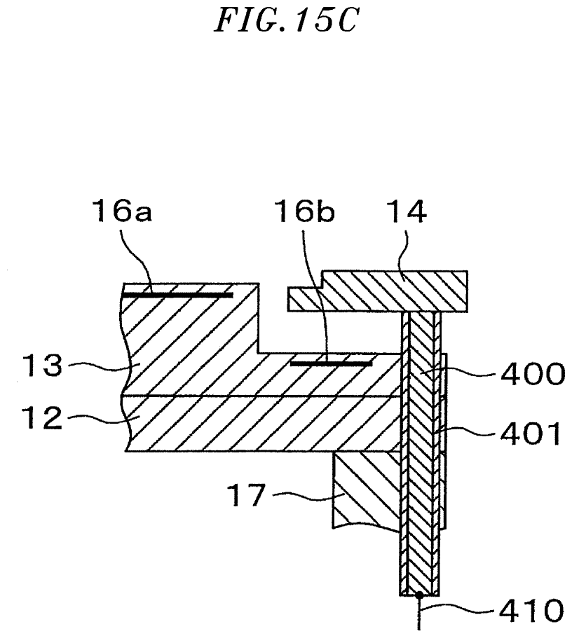

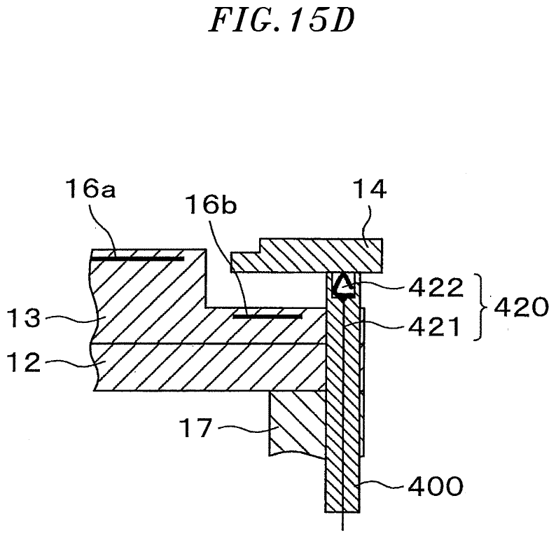

Next, as a contract structure with the edge ring 14, examples other than the examples illustrated in FIG. 9, and FIGS. 10A to 10F will be described. Each of FIGS. 14A to 14D and FIGS. 15A to 15D illustrates another example of the configuration of the connector.

Each of FIGS. 14A to 14D illustrates an example in which a lifter pin 300 of the driving device 70 is made of the insulating material and a connector 310 as the conductor is provided inside the lifter pin 300.

As illustrated in FIG. 14A, the driving device 70 may have the lifter pin 300 instead of the lifter pin 71 of the embodiment. The lifter pin 300 extends from the lower surface of the edge ring 14 in the vertical direction, and is provided to penetrate the electrostatic chuck 13, the lower electrode 12, the support member 17, and the bottom of the chamber 10. A space between the lifter pin 300 and the chamber 10 is sealed in order to seal the inside of the chamber 10. The lifter pin 300 is made of the insulating material. Further, the lifter pin 300 is configured to be movable in the vertical direction by a driving source 72 provided outside the chamber 10.

Inside the lifter pin 300, the connector 10 which is a conductive wire extending in the vertical direction is provided. The connector 310 directly connects the edge ring 14 and the lifter pin 300, and connects the edge ring 14 and the second variable passive element 61. Specifically, one end of the connector 310 is connected to the second variable passive element 61 and the other end is exposed on the upper surface of the lifter pin 300 and is in contact with the lower surface of the edge ring 14.

As illustrated in FIGS. 14B and 14C, the connector 310 provided inside the lifter pin 300 may have a conductive structure 11 and a conductive elastic member 312. The conductive structure 311 connects the edge ring 14 and the second variable passive element 61 via the conductive elastic member 312. Specifically, one end of the conductive structure 311 is connected to the second variable passive element 61 and the other end is exposed in an upper space inside the lifter pin 300 and is in contact with the conductive elastic member 312.

The conductive elastic member 312 is provided in the upper space inside the lifter pin 300. The conductive elastic member 312 is in contact with each of the lower surfaces of the conductive structure 311 and the edge ring 14. Further, the conductive elastic member 312 is made of a conductor such as metal. The configuration of the conductive elastic member 312 is not particularly limited, but for example, as illustrated in FIG. 14B, a plate spring having elasticity to which force is applied in the vertical direction may be used and as illustrated in FIG. 14C, a wire connecting the conductive structure 311 and the edge ring 14 may be used. Alternatively, as the conductive elastic member 312, the coil spring illustrated in FIG. 10B, the spring illustrated in FIG. 10C, the pin illustrated in FIG. 10D, etc. may be used. In this case, the edge ring 14 and the second variable passive element 61 are electrically connected via the conductive elastic member 312 and the conductive structure 311.

As illustrated in FIG. 14D, the lifter pin 300 has a hollow cylindrical shape in which the upper and lower surfaces are opened, and the connector 310 provided inside the lifter pin 300 may have another conductive structure (second conductive structure) 313 in addition to the conductive structure (first conductive structure) 311 and the conductive elastic member 312. The conductive structure 313 is provided on an inner surface of the lifter pin 300. The conductive structure 313 may be, for example, the metallic membrane or a metallic cylinder.

The conductive structure 311 is connected to a lower end of the conductive structure 311. The conductive elastic member 312 is connected to an upper end of the conductive structure 313. In this case, the edge ring 14 and the second variable passive element 61 are electrically connected via the conductive elastic member 312, the conductive structure 313, and the conductive structure 311.

Hereinabove, even when any connector 310 illustrated in FIGS. 14A to 14D is used, the edge ring 14 and the second variable passive element 61 may be electrically directly connected via the connector 310. Therefore, the frequency of the high-frequency power LF may be set to a low frequency of 5 MHz or less, and the controllability of the ion energy may be enhanced.

Further, since the connector 310 of the above embodiment is provided inside the lifter pin 300 made of the insulating material, the connector 301 need not have the configuration protected from the plasma.

Each of FIGS. 15A to 15D illustrates an example in which a lifter pin 400 of the driving device 70 is made of the conductive material and a lifter pin 400 itself constitutes the connector.

As illustrated in FIG. 15A, the driving device 70 may have the lifter pin 400 instead of the lifter pins 71 and 300 of the embodiment. The lifter pin 400 extends from the lower surface of the edge ring 14 in the vertical direction, and is provided to penetrate the electrostatic chuck 13, the lower electrode 12, the support member 17, and the bottom of the chamber 10. A space between the lifter pin 400 and the chamber 10 is sealed in order to seal the inside of the chamber 10. The lifter pin 400 is made of the conductive material. Further, the lifter pin 400 is configured to be movable in the vertical direction by a driving source 72 provided outside the chamber 10.

A conductive structure 410 is connected to the lower end of the lifter pin 400. The conductive structure 410 is connected to the second variable passive element 61. In this case, the edge ring 14 and the second variable passive element 61 are electrically connected via the lifter pin 400 and the conductive structure 410.

The lifter pin 400 preferably has a configuration of being protected from the plasma when the edge ring 14 is raised by the driving device 70. Each of FIGS. 15B and 15C illustrates an example of the plasma countermeasure of the lifter pin 400.

As illustrated in FIG. 15B, the additional edge ring 210 illustrated in FIG. 11B may be provided inside the lifter pin 400 on the upper surface of the lower electrode 12. In this case, by the additional edge ring 210, the plasma may be suppressed from turning into the lifter pin 400, and the lifter pin 400 may be protected. Further, the configuration of suppressing the plasma from turning into the lifter pin 400 is not limited thereto, and any configuration of FIGS. 11A, and FIGS. 11C to 11G may be applied.

As illustrated in FIG. 15C, an insulating member 401 having plasma-resistance may be provided on an outer surface of the lifter pin 400. The insulating member 401 may be a membrane of an insulator or a cylinder of made of an insulator material. In this case, the lifter pin 400 may be protected from the plasma by the insulating member 401. Further, in the configuration of FIG. 15B, the insulating member 401 illustrated in FIG. 15C may be further provided.

Hereinabove, even in any case illustrated in FIGS. 15A to 15C, the edge ring 15 and the second variable passive element 61 may be electrically directly connected via the lifter pin 400. Therefore, the frequency of the high-frequency power LF may be set to a low frequency of 5 MHz or less, and the controllability of the ion energy may be enhanced.

Further, in FIGS. 15A to 15C, the lifter pin 400 itself constitutes the connector, but as illustrated in FIG. 15D, a connector 420 as the conductor may be further provided inside the lifter pin 400. The connector 420 may have a conductive structure 421 and a conductive elastic member 422. The conductive structure 421 connects the edge ring 14 and the second variable passive element 61 via the conductive elastic member 422. Specifically, one end of the conductive structure 421 is connected to the second variable passive element 61 and the other end is exposed in an upper space inside the lifter pin 400 and is in contact with the conductive elastic member 422. Further, the conducive structure 410 is included in the conductive structure 421.

The conductive elastic member 422 is provided in the upper space inside the lifter pin 400. The conductive elastic member 422 is in contact with each of the lower surfaces of the conductive structure 421 and the edge ring 14. Further, the conductive elastic member 422 is made of a conductor such as metal. The configuration of the conductive elastic member 422 is not particularly limited, but for example, the plate spring to which the force is applied in the vertical direction illustrated in FIG. 10A may be used. Alternatively, the coil spring illustrated in FIG. 10B, the spring illustrated in FIG. 10C, the pin illustrated in FIG. 10D, the wire illustrated in FIG. 10E, etc. may be used. In this case, the edge ring 14 and the second variable passive element 61 are electrically connected via the conductive elastic member 422 and the conductive structure 421 in addition to the lifter pin 400. Further, since resistance by the contact of the lifter pin 400 and the conductive elastic member 422 may be suppressed, the edge ring 14 and the second variable passive element 61 may be more appropriately connected.

### Other Embodiments

In the etching device 1 of the above embodiment, a direct current (DC) power supply 62, a switching unit 63, a first RF filter 64, and a second RF filter 65 may be further provided. The first RF filter 64 and the second RF filter 65 are provided instead of the first variable passive element 60 and the second variable passive element 61, respectively. The first RF filter 64, the second RF filter 65, the switching unit 63, and the DC power supply 62 are arranged from the edge ring 14 side in this order. That is, the DC power supply 62 is electrically connected to the edge ring 14 via the switching unit 63, the second RF filter 65, and the first RF filter 64. Further, in the present embodiment, the DC power supply 62 is connected to the ground potential.

The DC power supply 62 is a power supply that generates negative-polarity DC voltage applied to the edge ring 14. Further, the DC power supply 62 is a variable DC power supply, and may adjust a height of the DC voltage.

The switching unit 63 is configured to stop the application of the DC voltage from the DC power supply 62 for the edge ring 14. Further, a circuit configuration of the switching unit 63 may be appropriately designed by those skilled in the art.

Each of the first RF filter 64 and the second RF filter 65 is a filter that attenuates the high-frequency power. The first RF filter 64 attenuates high-frequency power of 40 MHz from the first RF power supply 50, for example. The second RF filter 65 attenuates high-frequency power of 400 kHz from the second RF power supply 51, for example.

In one example, in the second RF filter 65, the impedance is configured to be variable. That is, the second RF filter 65 includes at least one variable passive element, and the impedance is variable. The variable passive element may be any one of a coil (inductor) or a condenser (capacitor), for example. Further, although is not limited to the coil and the condenser, even any variable impedance element such as an element such as a diode, etc. may achieve a similar function. The number or positions of variable passive elements may also be appropriately designed by those skilled in the art. Further, the element itself need not be variable, and for example, a plurality of elements in which the impedance has a fixed value is provided, and the impedance may be variable by switching a combination of the elements in which the impedance has the fixed value by using a switching circuit. Further, now, each of the circuit configurations of the second RF filter 65 and the first RF filter 64 may be appropriately designed by those skilled in the art.

Further, the etching device 1 may further have a measurer (not illustrated) that measures magnetic bias voltage (or magnetic bias voltage of the lower electrode 12 or the wafer W) of the edge ring 14. Further, the configuration of the measurer may be appropriately designed by those skilled in the art.

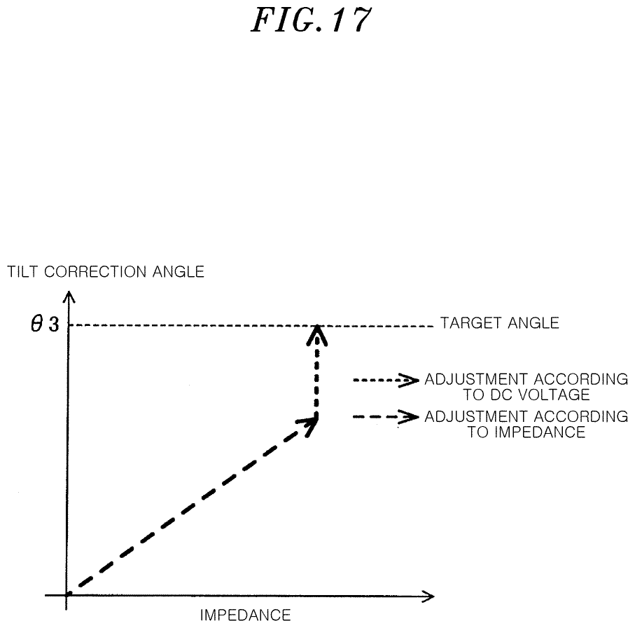

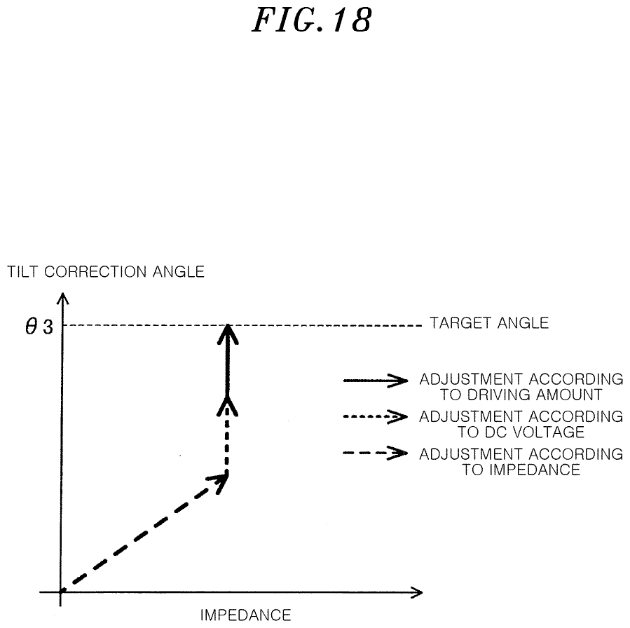

Next, a method for controlling the tilt angle by using the etching device 1 of the present embodiment will be described. In the present embodiment, in addition to the adjustment of the driving amount of the driving device 70 and the adjustment of the impedance of the second RF filter 65 in the embodiment, the DC voltage from the DC power supply 62 is adjusted. That is, two selected from a group at least consisting of the driving amount of the driving device 70, the impedance of the second RF filter 65, and the DC voltage from the DC power supply 62 are adjusted to control the tilt angle. Each of FIGS. 17 and 18 illustrates an example of a method for controlling the tilt angle in the present embodiment.

In the example illustrated in FIG. 17, first, the impedance of the second RF filter 65 is adjusted to correct the tilt angle. Next, when the impedance reaches a predetermined value, e.g., an upper limit value, the DC voltage from the DC power supply 62 is adjusted and the tilt correction angle is adjusted to the target angle 83 to set the tilt angle to 0 degree.

In the DC power supply 62, the DC voltage applied to the edge ring 14 is set to negative-polarity voltage having a sum of an absolute value of magnetic bias voltage Vdc and a set value ΔV as the absolute, i.e., −(|Vdc|+ΔV). The magnetic bias voltage Vdc is the magnetic bias voltage of the wafer W, and one or both high-frequency power is supplied, and further, is magnetic bias voltage of the lower electrode 12 when the DC voltage from the DC power supply 62 is not applied to the lower electrode 12. The set value ΔV is given by the controller 100.

The controller 100 sets the impedance of the second RF filter 65 from the exhaustion amount of the edge ring 14 similarly to the setting of the driving amount of the driving device 70 and the setting of the impedance of the second RF filter 65 in the embodiment. The set value ΔV is determined.

The controller 100 may use a difference between an initial thickness of the edge ring 14 and for example, a thickness of the edge ring 14 measured by using a measurer such as a laser measurer or a camera as the exhaustion amount of the edge ring 14 in determining the set value ΔV. Further, for example, the exhaustion amount of the edge ring 14 may be estimated from a change in mass of the edge ring 14 measured by a measurer such as a mass meter. Alternatively, the controller 100 may estimate the exhaustion amount of the edge ring 14 from a specific parameter by using a predetermined other function or table in order to determine the set value ΔV. The specific parameter may be any one of the magnetic bias voltage Vdc, a wave height Vpp of the high-frequency power HF or the high-frequency power LF, a load impedance, electrical characteristics of the edge ring 14 or around the edge ring 14, etc. The electrical characteristics of the edge ring or around the edge ring 14 may be any one of voltage and current values of a predetermined place of the edge ring 14 or around the edge ring 14, a resistance value including the edge ring 14, etc. Other function or table is predetermined to determine the relationship between the specific parameter and the exhaustion amount of the edge ring 14. In order to estimate the exhaustion amount of the edge ring 14, under setting of a measurement condition for estimating the exhaustion amount, i.e., the high-frequency power HF, the high-frequency power LF, pressure in the processing space S, and a flow rate of the processing gas, the etching device 1 is operated before executing actual etching or at the time of maintenance of the etching device 1. In addition, the specific parameter is acquired and the exhaustion amount of the edge ring 14 is specified by inputting the specific parameter into the separate function or referring to the table by using the specific parameter.

In the etching device 1, during etching, i.e., during a period in which one or both high-frequency power of the high-frequency power HF and the high-frequency power LF is supplied, the DC voltage is applied to the edge ring 14 from the DC power supply 62. As a result, the shape of the sheath above the edge ring 14 and the edge area of the wafer W is controlled, and as a result, the incident direction of the ion on the edge area of the wafer W is reduced and the tilt angle is controlled. As a result, throughout an entire area of the wafer W, the concave portion which is substantially parallel to the thickness direction of the wafer W is formed.

More specifically, during etching, the magnetic bias voltage Vdc is measured by a measurer (not illustrated). Further, the DC voltage is applied to the edge ring 14 from the DC power supply 62. A value of the DC voltage applied to the edge ring 14 is −(|Vdc|+ΔV) as described above. |Vdc| represents an absolute value of a measurement value of the magnetic bias voltage Vdc acquired by the measurer just before, and ΔV represents a set value determined by the controller 100. The DC voltage applied to the edge ring 14 from the magnetic bias voltage Vdc measured during etching is determined as such. Then, even though the magnetic bias voltage Vdc is changed, the DC voltage generated by the DC power supply 62 is corrected, and the tilt angle is appropriately corrected.

Further, in the example illustrated in FIG. 17, the driving amount of the driving device 70 may be adjusted instead of the impedance of the second RF filter 65. That is, by adjusting the driving amount of the driving device 70 and the DC voltage from the DC power supply 62, the tilt angle may be corrected.

In the example illustrated in FIG. 18, first, the impedance of the second RF filter 65 is adjusted to correct the tilt angle. Next, when the impedance reaches a predetermined value, e.g., an upper limit value, the tilt angle is corrected by adjusting the DC voltage from the DC power supply 62.

Here, when the absolute value of the DC voltage is set to a too large value, discharge occurs between the wafer W and the edge ring 14. Therefore, there is a limit in DC voltage which may be applied to the edge ring 14, and even though the tilt angle is intended to be controlled only by adjusting the DC voltage, there is a limit in the control range.

Therefore, when the absolute value of the DC voltage reaches a predetermined value, e.g., an upper limit value, the driving amount of the driving device 70 is adjusted and the tilt correction angle is adjusted to the target angle θ3 to set the tilt angle to 0 degree.

As described above, according to the present embodiment, the adjustment range of the tilt angle may be increased by performing the adjustment of the DC voltage from the DC power supply 62 in addition to the adjustment of the impedance of the second RF filter 65 and the adjustment of the driving amount of the driving device 70. Therefore, the tilt angle may be appropriately controlled, that is, the incident direction of the ion may be appropriately adjusted to evenly perform the etching.

Further, in controlling the tilt angle, a combination of the adjustment of the impedance of the second RF filter 65, the adjustment of the driving amount of the driving device 70, and the DC voltage from the DC power supply 62 may be arbitrarily designed.

Further, the adjustment of the impedance of the second RF filter 65, the adjustment of the driving amount of the driving device 70, and the DC voltage from the DC power supply 62 may be individually performed, but may be simultaneously performed.

In the above embodiment, the DC power supply 62 is connected to the edge ring 14 via the switching unit 63, the second RF filter 65, and the first RF filter 64, but a power meter applying the DC voltage to the edge ring 14 is not limited thereto. For example, the DC power supply 62 may be electrically connected to the edge ring 14 via the switching unit 63, the second RF filter 65, the first RF filter 64, and the lower electrode 12. In this case, the lower electrode 12 and the edge ring 14 are directly electrically coupled to each other, and the magnetic bias voltage of the edge ring 14 is the same as the magnetic bias voltage of the lower electrode 12.

Here, when the lower electrode 12 and the edge ring 14 are directly coupled to each other, for example, a sheath thickness on the edge ring 14 may not be adjusted by a capacity under the edge ring 14 determined in a hard structure, and even though the DC voltage is not applied, an outer tilt state may occur. In this regard, in the present disclosure, since the tilt angle may be controlled by adjusting the DC voltage from the DC power supply 62, the impedance of the second RF filter 65, and the driving amount of the driving device 70, the tilt angle may be adjusted to 0 degree by changing the tilt angle to the inner side.

Further, in the above embodiment, the impedance of the second RF filter 65 is variable, but the impedance of the first RF filter 64 may be variable and the impedances of both RF filters 64 and 65 may be variable. In this case, the first RF filter 64 includes at least one variable passive element. Further, in the above embodiment, two RF filters 64 and 65 are provided for the DC power supply 62, but the number of RF filters is not limited thereto, and for example, one RF filter may be provided. Further, in the above embodiment, the second RF filter 65 (first RF filter 64) includes at least one variable passive element and the impedance is variable, but a configuration in which the impedance is variable is not limited thereto. For example, a device in which the impedance of the RF filter is changeable may be connected to an RF filter in which the impedance is variable or fixed. That is, the RF filter in which the impedance is variable may be constituted by the RF filter and a device which is connected to the RF filter and is capable of changing the impedance of the RF filter. Further, the RF filter includes at least one variable passive element and the impedance is variable, but as the RF filter, an RF filter in which the impedance is not variable is used, so the variable passive element may be provided outside the RF filter.

### Other Embodiments

In the above embodiment, the adjustment of the driving device 70, the adjustment of the impedance of the second variable passive element 61 (second RF filter 65), and the adjustment of the DC voltage from the DC power supply 62 are performed according to the exhaustion amount of the edge ring 14, but adjustment timings of the driving amount the impedance, and the DC voltage are not limited thereto. For example, the driving amount, the impedance, and the DC voltage may be adjusted according to the processing time of the wafer W. Alternatively, for example, the adjustment timings of the driving amount, the impedance, and the DC voltage may be determined by combining the processing time of the wafer W, e.g., a predetermined parameter such as the high-frequency power.

### Other Embodiments

The etching device 1 of the above embodiment is the capacitively coupled etching device, but the etching device according to the present disclosure is not limited thereto.

For example, the etching device may be an inductively coupled etching device.

It should be considered that the disclosed embodiment as an example is not limited in all points. Various forms of the embodiment may be omitted, substituted, and changed without departing from the appended claims and the spirit.

The embodiment of the present disclosure further includes the following aspect.

### APPENDIX 1

A plasma processing apparatus comprising:

a plasma processing chamber;

a substrate support disposed in the plasma processing chamber, and including a lower electrode, an electrostatic chuck, and an edge ring disposed to surround a substrate mounted on the electrostatic chuck;

a driving device configured to move the edge ring in a vertical direction;

an upper electrode disposed above the substrate support;

a source RF power supply configured to supply source RF power to the upper electrode or the lower electrode to generate plasma from gas in the plasma processing chamber;

a bias RF power supply configured to supply bias RF power to the lower electrode;

at least one conductor contacting with the edge ring;

a DC power supply configured to apply negative-polarity DC voltage to the edge ring via the at least one conductor;

an RF filter electrically connected between the at least one conductor and the DC power supply, and including at least one variable passive element; and

a controller configured to control the driving device and the at least one variable passive element, and adjust an incident angle of an ion in the plasma with respect to an edge area of the substrate mounted on the electrostatic chuck.

### APPENDIX 2

The plasma processing apparatus of appendix 1, wherein the driving device includes

a lifter pin configured to support the edge ring, and

a driving source configured to move the lifter pin in the vertical direction.

### APPENDIX 3

The plasma processing apparatus of appendix 2, wherein the surface of the lifter pin is at least made of an insulating material.

### APPENDIX 4

The plasma processing apparatus of appendix 3, wherein the at least one conductor includes a conductive wire which extends in the vertical direction in the lifter pin, and

one end of the conductive wire is in contact with the edge ring.

### APPENDIX 5

The plasma processing apparatus of appendix 3, wherein the at least one conductor includes a conductive elastic member which is in contact with the edge ring.

### APPENDIX 6

The plasma processing apparatus of appendix 5, wherein the conductive elastic member is disposed in the lifter pin.

### APPENDIX 7

The plasma processing apparatus of appendix 5, wherein the conducive elastic member is disposed between the edge ring and the electrostatic chuck.

### APPENDIX 8

The plasma processing apparatus of appendix 7, further comprising:

an additional edge ring disposed between the edge ring and the electrostatic chuck.

### APPENDIX 9

The plasma processing apparatus of appendix 8, wherein the additional edge ring is made of an insulating material and disposed at an inner side than the conductive elastic member.

### APPENDIX 10

The plasma processing apparatus of appendix 9, wherein the edge ring has a protrusion on a lower surface thereof.

### APPENDIX 11

The plasma processing apparatus of appendix 8, wherein the additional edge ring is made of a conductive material, and

the conducive elastic member is disposed between the edge ring and the additional edge ring.

### APPENDIX 12

The plasma processing apparatus of any one of appendices 1 to 11, wherein the edge ring has at least one conductive membrane contacting with the at least one conductor.

### APPENDIX 13

The plasma processing apparatus of any one of appendices 1 to 11, wherein the at least one conductor includes a plurality of conductors disposed at an equal interval in a circumferential direction of the edge ring on a plan view.

### APPENDIX 14

The plasma processing apparatus of any one of appendices 1 to 11, wherein the edge ring is conductive.

### APPENDIX 15

A plasma processing apparatus comprising:

a plasma processing chamber;

a substrate support disposed in the plasma processing chamber, and including an electrostatic chuck, and an edge ring disposed to surround a substrate mounted on the electrostatic chuck;

a driving device configured to move the edge ring in a vertical direction;

an RF power supply configured to generate RF power to generate plasma from gas in the plasma processing chamber;

at least one conductor contacting with the edge ring;

at least one variable passive element electrically connected to the at least one conductor; and

a controller configured to control the driving device and the at least one variable passive element, and adjust an incident angle of an ion in the plasma for an edge area of the substrate mounted on the electrostatic chuck.

### APPENDIX 16

The plasma processing apparatus of appendix 15, wherein the driving device includes

a lifter pin configured to support the edge ring, and

a driving source configured to move the lifter pin in the vertical direction.

### APPENDIX 17

The plasma processing apparatus of appendix 16, wherein the surface of the lifter pin is at least made of an insulating material.

### APPENDIX 18

The plasma processing apparatus of appendix 17, wherein the at least one conductor includes a conductive wire which extends in the vertical direction in the lifter pin, and

one end of the conductive wire is electrically and physically connected to the edge ring.

### APPENDIX 19

An etching method using a plasma processing apparatus, wherein the plasma processing apparatus includes,

a plasma processing chamber,

a substrate support disposed in the plasma processing chamber, and including an electrostatic chuck, and an edge ring disposed to surround a substrate mounted on the electrostatic chuck;

at least one conductor electrically and physically connected to the edge ring, and

at least one variable passive element electrically connected to the at least one conductor, and

the etching method includes:

(a) mounting a substrate on the electrostatic chuck,

(b) generating plasma from gas in the plasma processing chamber,

(c) etching the substrate with the generated plasma,

(d) adjusting an incident angle of an ion in the plasma for an edge area of the substrate, and the adjusting process includes

(d1) moving the edge ring in a vertical direction, and

(d2) adjusting the at least one variable passive element.

1. A plasma processing apparatus comprising:
a plasma processing chamber;
a substrate support disposed in the plasma processing chamber, and including a lower electrode, an electrostatic chuck, and an edge ring disposed to surround a substrate mounted on the electrostatic chuck;
a driving device configured to move the edge ring in a vertical direction;
an upper electrode disposed above the substrate support;
a source RF power supply configured to supply source RF power to the upper electrode or the lower electrode to generate plasma from gas in the plasma processing chamber;
a bias RF power supply configured to supply bias RF power to the lower electrode;
at least one conductor contacting with the edge ring;
a DC power supply configured to apply negative-polarity DC voltage to the edge ring via the at least one conductor;
an RF filter electrically connected between the at least one conductor and the DC power supply, and including at least one variable passive element; and
a controller configured to control the driving device and the at least one variable passive element, and adjust an incident angle of an ion in the plasma with respect to an edge area of the substrate mounted on the electrostatic chuck.

2. The plasma processing apparatus of claim 1, wherein the driving device includes
a lifter pin configured to support the edge ring, and
a driving source configured to move the lifter pin in the vertical direction.

3. The plasma processing apparatus of claim 2, wherein the surface of the lifter pin is at least made of an insulating material.

4. The plasma processing apparatus of claim 3, wherein the at least one conductor includes a conductive wire which extends in the vertical direction in the lifter pin, and
one end of the conductive wire is in contact with the edge ring.

5. The plasma processing apparatus of claim 3, wherein the at least one conductor includes a conductive elastic member which is in contact with the edge ring.

6. The plasma processing apparatus of claim 5, wherein the conductive elastic member is disposed in the lifter pin.

7. The plasma processing apparatus of claim 5, wherein the conducive elastic member is disposed between the edge ring and the electrostatic chuck.

8. The plasma processing apparatus of claim 7, further comprising:
an additional edge ring disposed between the edge ring and the electrostatic chuck.

9. The plasma processing apparatus of claim 8, wherein the additional edge ring is made of an insulating material and disposed at an inner side than the conductive elastic member.

10. The plasma processing apparatus of claim 9, wherein the edge ring has a protrusion on a lower surface thereof.

11. The plasma processing apparatus of claim 8, wherein the additional edge ring is made of a conductive material, and
the conducive elastic member is disposed between the edge ring and the additional edge ring.

12. The plasma processing apparatus of claim 1, wherein the edge ring has at least one conductive membrane contacting with the at least one conductor.

13. The plasma processing apparatus of claim 1, wherein the at least one conductor includes a plurality of conductors disposed at an equal interval in a circumferential direction of the edge ring on a plan view.

14. The plasma processing apparatus of claim 1, wherein the edge ring is conductive.

15. A plasma processing apparatus comprising:
a plasma processing chamber;
a substrate support disposed in the plasma processing chamber, and including an electrostatic chuck, and an edge ring disposed to surround a substrate mounted on the electrostatic chuck;
a driving device configured to move the edge ring in a vertical direction;
an RF power supply configured to generate RF power to generate plasma from gas in the plasma processing chamber;
at least one conductor contacting with the edge ring;
at least one variable passive element electrically connected to the at least one conductor; and
a controller configured to control the driving device and the at least one variable passive element, and adjust an incident angle of an ion in the plasma for an edge area of the substrate mounted on the electrostatic chuck.

16. The plasma processing apparatus of claim 15, wherein the driving device includes
a lifter pin configured to support the edge ring, and
a driving source configured to move the lifter pin in the vertical direction.

17. The plasma processing apparatus of claim 16, wherein the surface of the lifter pin is at least made of an insulating material.

18. The plasma processing apparatus of claim 17, wherein the at least one conductor includes a conductive wire which extends in the vertical direction in the lifter pin, and
one end of the conductive wire is electrically and physically connected to the edge ring.

19. An etching method using a plasma processing apparatus, wherein the plasma processing apparatus includes,
a plasma processing chamber,
a substrate support disposed in the plasma processing chamber, and including an electrostatic chuck, and an edge ring disposed to surround a substrate mounted on the electrostatic chuck;
at least one conductor electrically and physically connected to the edge ring, and
at least one variable passive element electrically connected to the at least one conductor, and
the etching method includes:
(a) mounting a substrate on the electrostatic chuck,
(b) generating plasma from gas in the plasma processing chamber,
(c) etching the substrate with the generated plasma,
(d) adjusting an incident angle of an ion in the plasma for an edge area of the substrate, and the adjusting process includes
(d1) moving the edge ring in a vertical direction, and
(d2) adjusting the at least one variable passive element.
